(19) United States
(12) Patent Application Publication
(10) Pub. No.: US 2025/0190675 A1
(43) Pub. Date: Jun. 12, 2025

(54) PIXEL-BASED RULE CHECK FOR LAYOUTS

(71) Applicant: D2S, Inc., San Jose, CA (US)

(72) Inventors: Mariusz A. Niewczas, San Jose, CA (US); Yefim G. Belenky, San Jose, CA (US); Abhishek Shendre, Fremont, CA (US); Michael Pomerantsev, San Jose, CA (US); Akira Fujimura, Saratoga, CA (US)

(21) Appl. No.: 18/922,354

(22) Filed: Oct. 21, 2024

Related U.S. Application Data
(60) Provisional application No. 63/676,610, filed on Jul. 29, 2024.
(60) Provisional application No. 63/650,887, filed on May 22, 2024.
(60) Provisional application No. 63/545,545, filed on Oct. 24, 2023.

(51) Int. Cl. G06F 30/398

(52) U.S. Cl. CPC G06F 30/398

(57) ABSTRACT

Some embodiments provide a method for performing pixel-based rule checking on a layout that is used in a process for designing or manufacturing an integrated circuit. This pixel-based method provides an optimal approach for performing rule checks for layouts having shapes with curvilinear contours (i.e., with curvilinear edges). This method in some embodiments performs the rule check on a per pixel-basis that is optimal for curvilinear edges on which one or more pixels reside. In some embodiments, the layout is a mask layout used to manufacture the IC, while in other embodiments, the layout is a design layout used to design the IC (e.g., a layout used during the physical design process).

### CLAIM OF BENEFIT TO PRIOR APPLICATIONS

This application claims benefit of U.S. Provisional Applications (1) 63/545,545 filed Oct. 24, 2023, (2) 63/650,887, filed May 22, 2024, and (3) 63/676,610, filed Jul. 29, 2024. All three provisional applications (namely, U.S. Provisional Applications 63/545,545, 63/650,887, and 63/676,610) are incorporated herein by reference.

### BACKGROUND

Optical lithography is commonly used to manufacture integrated circuits on semiconductors. Optical lithography is a printing process in which a lithographic mask or photomask manufactured from a reticle is used to form patterns on a substrate (e.g., a semiconductor or silicon wafer) to create an integrated circuit (IC). Extreme ultraviolet (EUV) or X-ray lithography are considered types of optical lithography.

The reticle or multiple reticles may contain a circuit pattern corresponding to an individual layer of the integrated circuit, and this pattern can be imaged onto a certain area on the substrate that has been coated with a layer of radiation-sensitive material known as photoresist or resist. Once the patterned layer is created, the layer may undergo various other processes such as etching, ion-implantation (doping), metallization, oxidation, and polishing. These processes are employed to finish an individual layer in the substrate. If several layers are required, this process is repeated for each layer. Through such processes, multiple integrated circuits can be defined on a wafer substrate. The wafer can then be cut to obtain individual IC dies. Each IC die can then be mounted into an individual chip package.

In the production or manufacturing of semiconductor devices, such as integrated circuits, maskless direct write processes may also be used to fabricate the semiconductor devices. A maskless direct write process is a printing process in which charged particle beam lithography is used to form patterns on a substrate such as a semiconductor or silicon wafer to create the integrated circuit. Desired patterns of a layer are written directly on the surface, which in this case is also the substrate. Once the patterned layer is created, the layer may undergo various other processes such as etching, ion-implantation (doping), metallization, oxidation, and polishing. These other processes are employed to finish an individual layer in the substrate. If several layers are required, the entire process is repeated for each new layer. Through such processes, multiple integrated circuits can be defined on a wafer substrate, which can then be cut to obtain individual IC dies that are mounted in individual chip packages. Some manufacturing processes combine optical lithography for some IC layers while using maskless direct write for other IC layers.

In optical lithography, a lithographic mask includes numerous geometric patterns (shapes) corresponding to the circuit components that are to be defined on the semiconductor substrate. The mask patterns are based on a design component and wiring shapes that are produced by EDA (electronic design automation) software. In designing these shapes, the EDA programs typically follow a set of pre-determined design rules.

These rules are set by processing, design, and end-use limitations. One example of an end-use limitation is to define the transistor geometry in a way to ensure that it operates at the required supply voltage. Also, design rules can define the space tolerance between circuit devices or interconnect lines, e.g., to ensure that the circuit devices or lines do not interact with one another in an undesirable manner (such as being too close to each other to cause a short circuit). The design rule limitations also reflect, among other things, the smallest dimensions that can be reliably fabricated. When referring to these small dimensions, one usually introduces the concept of a critical dimension. Critical dimensions are, for instance, defined as the important widths or areas of a feature, the important space between two features, or important space areas-those dimensions requiring exquisite control.

As mentioned above, optical lithography manufactures a circuit design on a substrate by exposing a reticle (referred to as a mask or a photomask) during charged particle beam lithography. As the critical dimensions of the circuit pattern become smaller and approach the resolution value of the exposure tool, the accurate transcription of the physical design produced by EDA tools to the actual circuit pattern developed on the resist layer becomes difficult.

To further the use of optical lithography to form patterns having features that are smaller than the light wavelength used in the optical lithography process, a process known as optical proximity correction (OPC) has been developed. OPC alters the physical design to compensate for distortions caused by effects such as optical diffraction and the optical interaction of features with proximate features. Resolution enhancement technologies (RET) performed with a reticle include OPC and inverse lithography technology (ILT). OPC may add sub-resolution lithographic features to mask patterns to reduce differences between the original physical design pattern, that is, the design, and the final created circuit pattern on the substrate.

The sub-resolution lithographic features interact with the original patterns in the physical design and with each other and compensate for proximity effects to improve the final created circuit pattern. One feature that is added to improve pattern formation is referred to as a “serif”. Serifs are small features that enhance precision or resiliency to manufacturing variation of printing of a particular feature. An example of a serif is a small feature that is positioned on a corner of a pattern to sharpen the corner in the final created image. Patterns that are intended to print on the substrate are referred to as main features.

It is conventional to discuss the OPC-decorated patterns to be written on a reticle in terms of main features, that is, features that reflect the design before OPC decoration, and OPC features, where OPC features might include serifs, jogs, sub-resolution assist features (SRAFs) and negative features. SRAFs are isolated shapes, unattached to the main feature, and are small enough not to print on the substrate, while serifs, jogs and negative features alter a main feature. OPC features are subject to various design rules, such as a rule based on the size of the smallest feature that can be created to the wafer using optical lithography. Other design rules may come from the mask manufacturing process or, if a character projection charged particle beam writing system is used to form the pattern on a reticle, from the stencil manufacturing process.

The photomasks of leading-edge nodes are becoming more and more curvilinear. Traditionally, target mask shapes are described as “Manhattan” geometry with axis-orthogonal edges, or sometimes with 45-degree edges. With the advent of multibeam mask writing, curvilinear mask target shapes have been enabled. OPC and ILT can optimize the resilience to wafer manufacturing variation better with curvilinear shapes than with Manhattan shapes. Manufacturable target shapes on masks are more resilient to mask manufacturing variation. For both mask manufacturing and the subsequent wafer manufacturing using those masks, a mask is less susceptible to mask manufacturing variation, and the wafer pattern resulting from using the mask is also less susceptible to wafer manufacturing variation. For this reason, semiconductor manufacturing in leading-edge nodes is shifting to curvilinear masks.

Mask rule check (MRC) is an important stage of mask writing process. After OPC and mask process correction (MPC), the data is ready to be fed into the mask writing machine. However, the data must be checked for adherence to some special “mask rules”. Those rules, essentially specify a contract between the OPC shop and mask shop: “if the OPC shop provides the mask geometry that follows the agreed upon mask rules, then the mask shop will transfer this geometry exactly on the semiconductor mask”. MRC rules specify, for example, the minimum area, width and spacing for shapes. Performance of such checks for mask designs having curvilinear shapes is not a trivial matter.

### SUMMARY

Some embodiments provide a method for performing pixel-based rule checking on a layout that is used in a process for designing or manufacturing an integrated circuit (IC). This pixel-based method provides an optimal approach for performing rule checks for layouts having shapes (e.g., patterns, interconnect wiring, vias, etc.) with curvilinear contours (i.e., with curvilinear edges). This method in some embodiments performs the rule check on a per pixel-basis that is optimal for curvilinear edges on which one or more pixels reside. In some embodiments, the layout is a mask layout used to manufacture the IC, while in other embodiments, the layout is a design layout used to design the IC (e.g., a layout used during the physical design process). The method of yet other embodiments is used to perform pixel-based rule checking for design or mask layouts that are created for designing and manufacturing other patterns on other types of substrates, such as flat-panel displays (e.g., monitors, televisions, glasses, etc.), curved displays (e.g., displays for virtual reality or augmented reality headsets), silicon interposers, micro-electromechanical systems (MEMS), etc.

The method in some embodiments performs a rasterization operation to generate pixel-based definitions for shapes in the layout from contour-based definitions that are used to define the shapes in the layout. No rasterization is needed in other embodiments, as the layout shapes are already defined in the pixel domain (e.g., by an ILT-based OPC tool). In some embodiments, the method assigns several pixels (e.g., several pixels anywhere in the layout, or several pixels that lie along one or more edges of one or more shapes in the layout) to different processing threads of a set of one or more processing units.

The method uses each particular processing thread that is assigned to each particular pixel to perform a rule check for the particular pixel. For instance, the method in some embodiments determines whether the particular pixel is on an edge that is within a threshold distance of another edge. For each particular edge that is identified to be within a threshold distance of each pixel's edge, the method then determines whether the identified particular edge violates a rule check.

In some embodiments, the threshold distance is a threshold distance that defines a search area (e.g., search window) for searching for nearby edges. The rule check in some of these embodiments includes a spacing check and/or a width check. The spacing check ensures that no two edges of two nearby shapes are closer than a threshold spacing distance. For such a check, an edge that a processing thread identifies is an edge of a shape that is different than the shape of the pixel to which the processing thread is assigned. The width check, on the other hand, ensures that no two edges of one shape are closer than a threshold width distance. Hence, for a width check, an edge that a processing thread identifies is an edge of the same shape of the pixel to which the thread is assigned.

In some embodiments, several different processing threads that are assigned to several different pixels concurrently execute on several different processing units of one computer or of several computers. The different processing units in some embodiments are different cores of one or more processors, such as central processing units (CPUs), graphics processing units (GPUs), or tensor processing units (TPUs). The different processing threads in some embodiments are similar threads and implement a single instruction multiple data (SIMD) compute approach for their assigned pixels. The SIMD compute approach is an optimal compute approach for parallel processing one instruction on multiple data sets. GPUs and TPUs are often used for such parallel processing of SIMD computations.

For its assigned pixel, each processing thread (1) receives the pixel-based definitions of the shapes, (2) analyzes the pixel-based definitions to generate any edge that is within a first threshold distance (e.g., specified by a search window) of the particular pixel, and (3) examines each generated edge to determine whether the generated edge violates an MRC rule. For these operations, each processing thread dynamically generates and stores edge data in a volatile runtime memory (e.g., RAM) of its processing unit's computer. This edge data is subsequently discarded from the volatile memory after the thread has completed its operation for its pixel.

The method in some embodiments examines each generated edge to determine whether the generated edge is within a second threshold distance of the particular pixel or of an edge on which the particular pixel resides. In some embodiments, a particular pixel's processing thread not only has to generate nearby edges on which nearby pixels reside but also has to generate the edge on which the particular pixel resides. To generate an edge, each pixel processing thread in some embodiments first generates a piecewise linear version of the edge, and then through a curve-fitting operation, convert the piecewise linear edge into another edge, which can be a curvilinear edge with one or more curvilinear (e.g., curved) segments.

In converting contour-definition of shapes to pixel definitions, the rasterization operation in some embodiments produces an image that includes numerous pixels. Each pixel in the produced image has a pixel value that is assigned to it by the rasterization operation. The pixel values fall into three categories (also called types below), which are (1) a first category of pixel values indicative of a pixel being completely within a shape, (2) a second category of pixel values indicative of a pixel being completely outside of any shape, and (3) a third category of pixel values for a pixel that is along an edge of a shape.

In some embodiments, the third category of pixel values are fractional values, while the first and second categories of pixel values are 1 and 0 values, respectively. In other embodiments, the pixel values are values in a range of values that are above and below a threshold value. In some of these embodiments, values below the threshold value are values that are associated with pixels being outside of any shape, while the threshold values are values along the boundaries of shapes, and values above the threshold value are values of pixels within a shape.

In some embodiments, each particular processing thread generates an edge for its particular pixel by implementing an edge detection and drawing process that (1) identifies pixel values of the third type that fall within the search window, and (2) generates an edge to connect neighboring identified pixel values of the third type. The edge detection and drawing process in some embodiments is a marching-square (MS) process. The generated edge can be a piecewise linear (PWL) edge formed by one or more straight edges, or a curved edge. In the former case, each straight edge in some embodiments is a straight-line segment that can be defined by reference to a first degree polynomial equation, such as y=mx+b, where x and y are coordinates along the line, m is the slope, and b is the y-intercept. Also, in some embodiments, each curved edge can be defined by reference to any one of several common ways to define a curve, such as a second degree or higher polynomial equation, a Bezier function, a spline function (B-spline function), etc.

The particular processing thread in some embodiments examines each edge (e.g., each PWL or curved edge) that it generates to determine whether it needs to modify the generated edge (e.g., modify a generated straight or curved edge to be a more accurate curved edge, or a more accurate PWL edge) to more accurately cover an area that matches the pixel values that are assigned (by the rasterization operation) to a region traversed by the edge. When the thread determines that it has to modify the generated edge, the thread in some embodiments uses the edge to generate a new, temporary, PWL edge or curved edge with the desired coverage area, and then uses this newly generated edge to perform the rule check (e.g., to perform its spacing or width spacing rule check) enforced by the thread.

Other embodiments perform pixel-based rule checking for a layout (e.g., an IC design or manufacturing layout) differently than some of the approaches described above. For instance, for a pixelated region of the layout, the pixel-based rule checking process of some embodiments (1) has several processing threads dynamically generate local edges for different pixels in a region of the layout, (2) stores these edges in a memory (e.g., a volatile runtime memory, such as RAM) shared among the processing threads, and then (3) uses the dynamically generated edges to perform pixel-based rule checking for different pixels in the region. In some of these embodiments, the pixel-based rule checking examines spacing rules for non-edge pixels (i.e., pixels that do not lie on an edge of an object in the layout) and edge pixels (i.e., pixels that lie on an edge of an object in the layout).

The preceding Summary is intended to serve as a brief introduction to some embodiments of the invention. It is not meant to be an introduction or overview of all inventive subject matter disclosed in this document. The Detailed Description that follows and the Drawings that are referred to in the Detailed Description will further describe the embodiments described in the Summary as well as other embodiments. Accordingly, to understand all the embodiments described by this document, a full review of the Summary, Detailed Description, the Drawings, and the Claims is needed. Moreover, the claimed subject matters are not to be limited by the illustrative details in the Summary, Detailed Description, and the Drawings.

### BRIEF DESCRIPTION OF FIGURES

The novel features of the invention are set forth in the appended claims. However, for purposes of explanation, several embodiments of the invention are set forth in the following figures.

FIG. 1 illustrates an example of a layout with several curvilinear shapes.

FIG. 2 illustrates examples of two types of rules that are often checked as part of DRC or MRC.

FIG. 3 illustrates the spacing distance between two nearby shapes with curved edges as the edges curve towards and away from each other.

FIG. 4 illustrates an example of a curved edge that is converted into a pixel-dose map through rasterization.

FIG. 5 illustrates a process that is used in some embodiments to efficiently perform rule checks on layout shapes with curvilinear boundary contours.

FIG. 6 illustrates an example of the output of the rasterization operation for two of the shapes of FIG. 1.

FIG. 7 presents a block diagram that conceptually illustrates several modules that perform the operations of the process.

FIG. 8 illustrates an example of a search window about a pixel on the right boundary of the shape.

FIG. 9 illustrates a process performed by a pixel processing thread.

FIGS. 10-12 illustrate an example of how some embodiments perform the marching square process to dynamically generate an edge for a pixel that falls within a search window.

FIG. 13 illustrates an example of an implied edge being generated for the corner of a shape that falls within a search window.

FIG. 14 illustrates a process that a pixel-processing thread performs to dynamically generate a local edge that traverses through its assigned pixel when this pixel lies on a contour boundary of a shape in the layout.

FIG. 15 illustrates a rule checking process that a thread performs for an MSG pixel that is assigned to it.

FIG. 16 illustrates a spacing rule check being performed for an MSG pixel.

FIG. 17 illustrates a process of some embodiments for flagging shapes of pixels associated with a violation for either manual or automatic correction.

FIG. 18 illustrates a process of some embodiments for automatic correction of shapes flagged for auto-correction.

FIG. 19 illustrates an example of auto-correcting a shape that violates a minimum width rule.

FIG. 20 illustrates an example of auto-correcting a shape that violates a minimum spacing rule.

FIG. 21 illustrates a process of some embodiments for designing and manufacturing an IC.

FIG. 22 conceptually illustrates an electronic system with which some embodiments are implemented.

### DETAILED DESCRIPTION

In the following detailed description of the invention, numerous details, examples, and embodiments of the invention are set forth and described. However, it will be clear and apparent to one skilled in the art that the invention is not limited to the embodiments set forth and that the invention may be practiced without some of the specific details and examples discussed.

Some embodiments provide a method for performing pixel-based rule checking on a layout that is used in a process for designing or manufacturing an integrated circuit. The pixel-based method of some embodiments uses multiple processing threads concurrently executing on multiple processing units to perform rule checks on individual pixels that lie along boundary contours of shapes (e.g., patterns, interconnect wiring, vias, etc.) in the layout. This pixel-based method provides an optimal approach for performing rule checks on layouts with shapes with curvilinear contours. This method in some embodiments performs the rule check on a per pixel-basis that is optimal for curvilinear edges on which one or more pixels reside. In some embodiments, the layout is a mask layout with its shapes being mask pattern shapes and the rule checks being mask rule checks (MRCs). In other embodiments, the layout is a design layout with its shapes being IC component shapes for an IC design and the rule checks being design rule checks (DRCs).

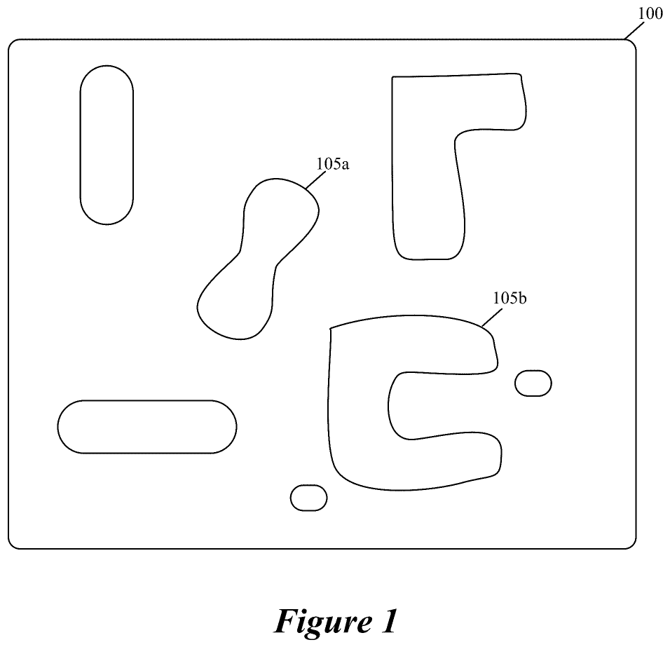

FIG. 1 illustrates an example of a layout 100 with several curvilinear shapes 105. Each of these shapes has a curvilinear contour. Although not shown, the shapes of a layout in some embodiments can also include shapes with only PWL edges (also called straight or rectilinear edges), shapes with only curved edges, and shapes with PWL and curved edges. In some embodiments, the layout 100 is a mask layout and the shapes 105 are mask pattern shapes that represent transparencies (also called holes or transparent areas) in the masks through which light can pass through. Such a mask layout is used to manufacture a mask, which, in turn, is then used to manufacture an IC through a lithographic process. In other embodiments, the layout 100 is a design layout and the shapes 105 are circuit components (e.g., transistor gates, etc.) and interconnects (e.g., wires and vias) in the design layout. In some embodiments, the design layout is the design layout after a physical design stage (e.g., after routing or compaction).

In some embodiments, a mask layout has an overall mask image for each device or wiring layer. The overall mask image for each layer can be decomposed into several individual mask images, for instance through the use of a coloring technique that assigns one of several different colors to each shape in the overall mask image in order to assign the shape to the individual mask image of that color. Each mask image of each layer can be used to produce a mask that can then be used to fabricate the components of that layer. The design layout in some embodiments has a layout for each device layer and each wiring layer, and the layout for each design/wiring layer includes the shapes of the components that are defined on that layer.

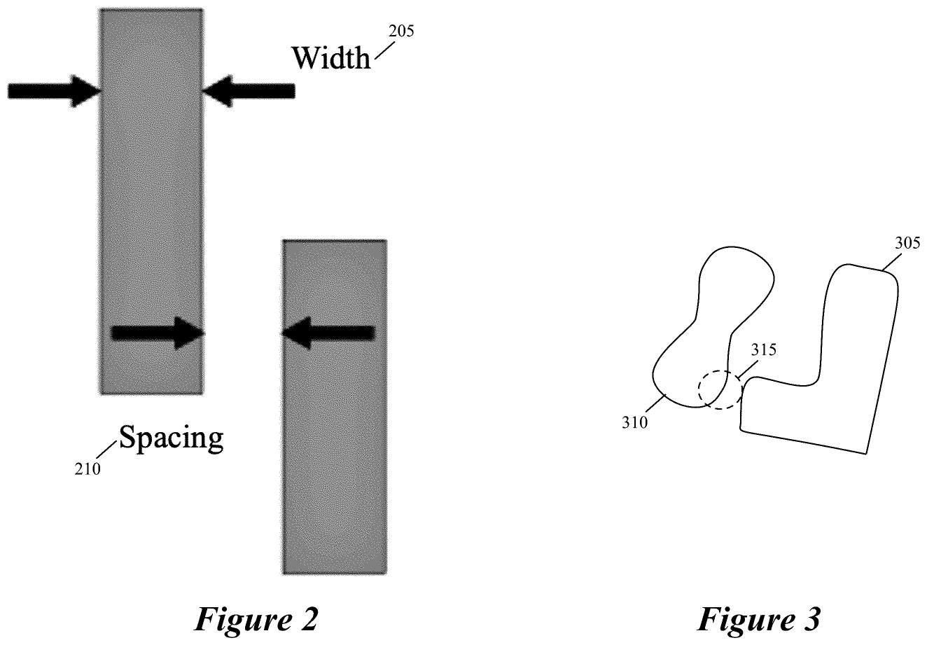

FIG. 2 illustrates examples of two types of rules that are often checked as part of DRC or MRC. These rules are a width rule that specifies the minimum width 205 of a shape (e.g., of a component or mask pattern), and a spacing rule that specifies the minimum spacing 210 between two shapes (e.g., two components or mask patterns). Examples of other types of rules that are checked by some embodiments include (1) minimum enclosure spacing rule that specifies the minimum spacing for one object (e.g., one metal contact on one layer) to overlap another object (e.g., another metal object on another layer), (2) minimum area rule that specifies a minimum area for a shape in the layout, and (3) a maximum local edge curvature rule that specifies a maximum allowed curvature for the contour of a shape in the layout.

The checking of these rules becomes more complicated when the shapes in the layout have curvilinear edges. For instance, FIG. 3 illustrates the spacing distance between two nearby shapes with curved edges 305 and 310 as the edges curve towards and away from each other. To identify the distance between the curved edges, a rule checker would have to identify the radius of the largest circle 315 that can have its center run along one edge without touching the other edge. Such an operation would be quite time consuming if it has to be performed for each curvilinear shape in the layout that is being examined.

Semiconductor manufacturing in leading-edge nodes are rapidly shifting to curvilinear masks. For strictly Manhattan designs, computing with rectangles and occasional triangles is acceptable, and better with CPU-based computing. However, for curvilinear designs where at least some parts of the design include curvilinear shapes, some embodiments use pixel-based computing with sufficient pixel resolution, as pixel-based computing is better, particularly for single-instruction multiple data (SIMD) computing, such as on GPUs.

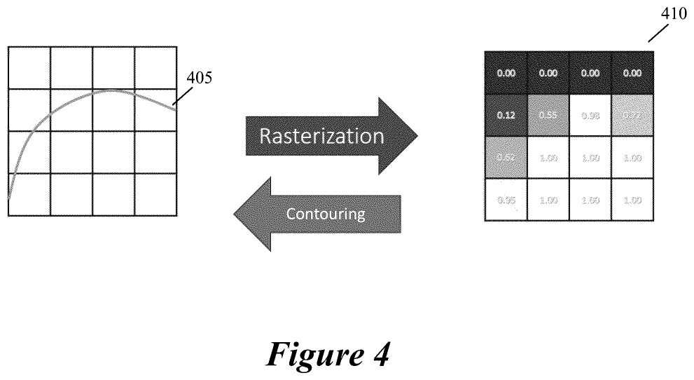

When some parts of the design and verification flow are contour-based, and other parts are pixel-based, some embodiments use rasterization and contouring operations to transition between the contour-based definitions and the pixel-based definitions. For some embodiments of the invention, FIG. 4 illustrates an example of a curved edge 405 that is converted into a pixel-dose map 410 through rasterization. This is an example of a raster tone map (RTM), in which the pixel data that is created by rasterization has three kinds of pixels: exterior pixels with a value 0, interior pixels with a value 1 and edge pixels with values greater than 0 and smaller than 1.

In some embodiments, edge pixels correspond to the areas where the original geometry data had an edge, and the dose value for any one edge pixel directly expresses the area of the pixel covered by the passing edge (e.g., is 0.9 when the edge occupies 0.9 (90%) of the pixel). The accuracy of rasterization depends on the pixel size used for sampling the geometries such that the pixel value, or dose, indicates the normalized area of the geometry data overlapping the corresponding pixel area. As indicated in FIG. 4, contouring is the opposite process to rasterization. Contouring reconstructs the geometry data from the pixel data.

Instead of RTM, other embodiments use continuous tone maps (CTMs) or quantized tone maps (QTMs). In such tone maps, the pixel values are in a range that starts below a threshold value and ends above a threshold value. In CTM or QTM, the data typically varies more gradually from pixel to pixel than the rasterized data. Also, in CTM or QTM of some embodiments, the pixels with values below the threshold value are exterior pixels, the pixels with values above the threshold value are interior pixels, and the pixels with values at or near the threshold values are edge pixels. CTM and QTM values are often used when the source of pixel data is computational lithography. QTM values are quantized two-dimensional values of a continuous function and the pixel values do not directly encode the area coverage.

Since both rasterization and contouring operations are computationally intensive, some embodiments stay in the pixel-based computing domain for purposes of efficiency. For instance, pixel-based MRC verification of some embodiments is performed as part of OPC/ILT or in mask process correction (MPC), and this verification is performed completely in the pixel domain in order to eliminate the need for conversion to and from the contour domain.

MRC has some rules that have evolved into very specific “corner cases” that are important for legacy mask writers but, arguably, not so much for modern mask writers. Adjustment of the rules for the modern machines will be easier if the data processing paradigm is changed to the pixel-centric model of some embodiments. Production of state-of-the-art IC masks requires the use of multi-beam mask writers that work in terms of pixels. One example of a multi-beam mask writer for the leading-edge nodes uses hundreds of thousands of electron beams operating in parallel, with each beam corresponding to a dose value of a specific pixel.

A previous generation of mask writers used a single beam with a variable shape aperture. These older machines, called VSB mask writers, did not operate in terms of pixels. The mask geometry processing methods developed over the last 30+ years have been tailored to how the older machines operate. Moreover, the vocabulary in which the mask rules are expressed is also natural for older machines. Other machines used lasers to expose the resist coated on the mask. Some of the laser writers are also multiple beam machines.

In contrast, the principle of operation of the multi-beam machine is that the raster data (“the pixels”) uniquely determines the shapes that are written on the mask. Hence, some embodiments use pixel-based MRC for masks written using the modern multi-beam machines instead of the contour-based, prior art MRC techniques. The pixel-centric MRC can be implemented in a natural way within the multi-beam machine data flow. Some multi-beam machines are integrated with a very powerful GPU-based supercomputer on which many pixel-based algorithms can be implemented with speeds that exceed 1-3 orders of magnitude of any known equivalent algorithms defined in the contour domain. The data flow inside the multi-beam machine is naturally represented as pixels. Using the pixel-based MRC approach of some embodiments avoids the required back-and-forth conversions from edge-based representation to the pixels of the current MRC techniques. The pixel-based MRC approach of some embodiments is also faster and more efficient, because operating in the contour domain introduces non-uniformity in the data flow, thus making it more complicated and slower.

The mask writing process begins once the mask design data has passed MRC. A photoresist is deposited on a specially prepared substrate that is called a mask blank. This photoresist is a substance sensitive to an energy source, for leading edge nodes, typically an electron beam (ebeam). Next, the multi-beam machine shoots several parallel electron beams (called beamlets) onto the photoresist. Each beam can have a different electron density, with some beams set to a high value while some others, for example, completely cut-off so that negligeable electron charge is delivered in some locations. This is how the patterning happens: the photoresist that has been exposed to electrons undergoes some chemical reactions that change its physical and chemical properties. The photoresist regions exposed and unexposed react differently to some special developing and etching agents that are applied later. The creation of patterns on masks relies on this different way of reacting even though there are several variants of photoresist and development processes. The electron beams determine the shapes that are created on the mask. These shapes are determined by the pixel values the machine uses to set the dose values of the electron beamlets. Under older approaches, the contour data delivered to the machine was changed into a raster image (i.e., rasterized) before it was used internally to write the mask. Under newer approaches, the pixel information is used directly and this more direct approach has the potential to streamline mask writing processes.

In sum, it is beneficial to perform mask rule checks in the pixel-domain as the runtime for this rule check does not explode like it does with polygonal manipulation as the vertex count goes up. It is possible to do the rule check in pixel-domain and not lose any theoretical precision or accuracy because masks (especially ones with curvilinear shapes) will often be written on multi-beam mask writers. Multi-beam mask writers often have a fixed aperture size. Hence, there is a known resolution limit in how the mask is going to be written. Inspection, repair, and metrology often use pixeled images to look at the data, and therefore the data will need to be in the pixel-domain ultimately. Regardless of the input shape, no matter how much granular (fine level) data exists, and no matter if a circle is described with vertices spaced 1 nm apart or 10 nm apart, the shape that can be projected on the physical mask is limited by the bandwidth dictated by the pixel size of the multibeam writer. Operating in the pixel-domain naturally takes that into account and ignores any unneeded precision that will get lost in the mask writing process anyway.

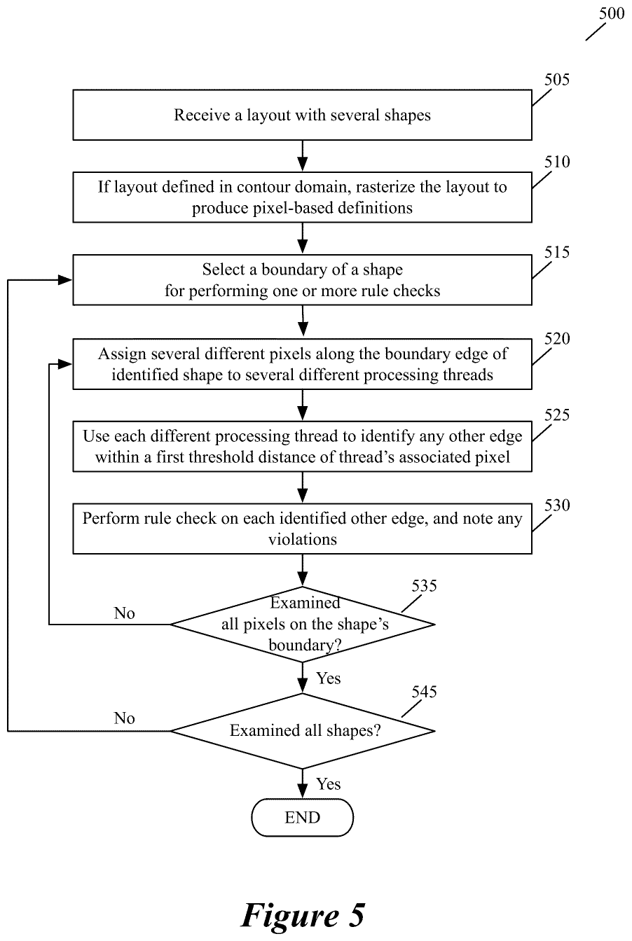

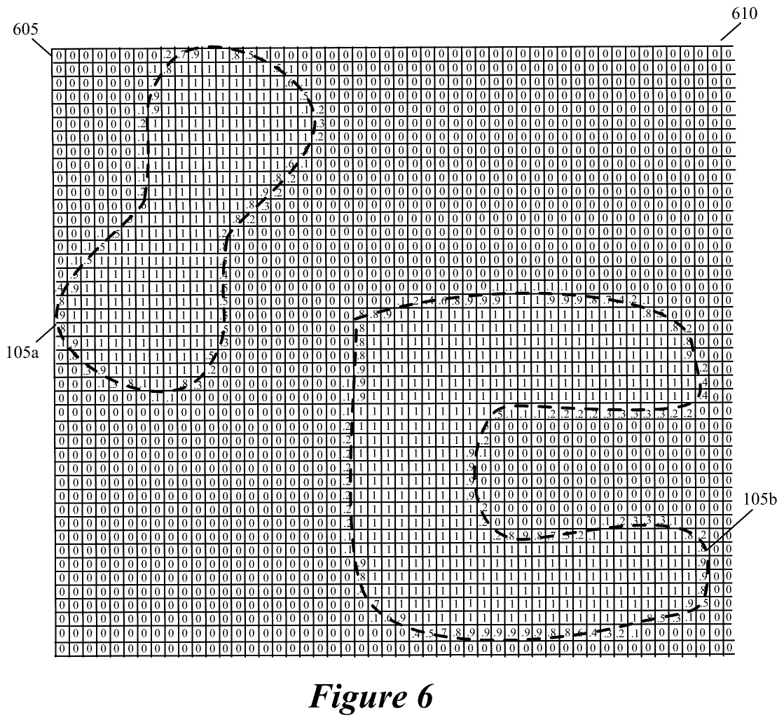

FIG. 5 illustrates a process 500 that is used in some embodiments to efficiently perform rule checks on layout shapes with curvilinear boundary contours (also called curvilinear boundary edges). The process 500 uses a pixel-based method that has multiple processing threads concurrently executing on multiple processing units to perform rule checks on individual pixels in the layout. In some embodiments, the process 500 is performed for only the pixels that lie along a shape's boundary contour (which can be formed by PWL edges and/or curved edges), while in other embodiments, the process 500 examines each pixel in a layout. The pixel-based approach of FIG. 5 is particularly optimal for shapes with curvilinear contours as it does not require edges along these contours to be predefined and stored on disk, as further described below.

As shown, the process 500 starts when it receives (at 505) a layout with several shapes. In some embodiments, the layout is a mask layout with its shapes being mask pattern shapes and the rule checks are mask rule checks (MRCs). In other embodiments, the layout is a design layout with its shapes being IC component shapes for an IC design and the rule checks are design rule checks (DRCs). The above-described FIG. 1 presents a layout 100 with several shapes 105 with curvilinear boundaries. In some embodiments, the received layout is defined in the pixel domain (e.g., the layout is the output of an ILT-based OPC tool), while in other embodiments the received layout is defined in the contour domain (i.e., each shape is defined by reference to geometric definition of the shape's boundary contour).

When the received layout is defined in the contour domain, the process 500 performs (at 510) a rasterization operation to generate pixel-based definitions for shapes in the received layout from contour-based definitions that are used to define the shapes in the layout. The rasterization operation produces a pixel-based image that represents the received layout. Each pixel in the produced image has a pixel value that is assigned to it by the rasterization operation. In some embodiments, the rasterization produces pixel values that fall into one of three categories (also called types below), which are (1) a first category of pixel values indicative of a pixel being completely within a shape, (2) a second category of pixel values indicative of a pixel being completely outside of any shape, and (3) a third category of pixel values for a pixel that is along an edge of a shape.

In some embodiments, the first category of pixel values corresponding to pixels that are completely within a shape are assigned a value 1, while the second category of pixel values that are completely outside of all shapes are assigned 0. In these embodiments, each third-category pixel that is along a shape's boundary is assigned a fractional value between 0 and 1, based on how much of the pixel is covered by the boundary edge. These values for the first, second and third categories are referred to as pixel dose values, as they relate to how much of the pixel is covered by a shape. The pixel dose is 1 when the pixel is fully covered by a shape, 0 when the pixel is not covered by any shape, and between 0 and 1 based on the percentage of the pixel that is covered by the shape (i.e., by the shape's boundary). As mentioned above and further described below, the pixel values in other embodiments are based on CTM or QTM values that fall in a range that starts below a threshold value and goes to a value above the threshold value.

FIG. 6 illustrates an example of the output of the rasterization operation for two of the shapes 105a and 105b of FIG. 1. The results of the rasterization are the square pixels 605 and the 0, 1, or fractional values assigned to these pixels. For purposes of correlating these values with the two shapes, the contours of the two shapes 105a and 105b are drawn with dashed lines over the pixel grid array 610 that defines the pixels 605. The contours of these shapes, however, are not expressly defined by a geometric definition in the image file. Rather, these contours are just identifiable through a series of fractional pixel values that form a boundary that encompasses a series of pixel values equal to 1. The pixels that are not covered by any shapes (i.e., the pixels on the exterior periphery of the boundary-defining pixels) are assigned 0 to signify that no shapes reside at those pixel locations.

At 515, the process 500 selects in the layout, a boundary of a shape for which it should perform one or more rule checks. In some embodiments, the process 500 selects this boundary by identifying a contiguous region of 1 values, with a boundary of 1 or fractional pixel values, surrounded by a contiguous region of 0 values. In FIG. 6 and the examples described below, it is assumed the process 500 initially selects the boundary of pixel values that were defined for the shape 105a in FIG. 1. As shown in FIG. 6, most of the boundary pixel values have a fractional value between 0 and 1, with a few of them having a value 1.

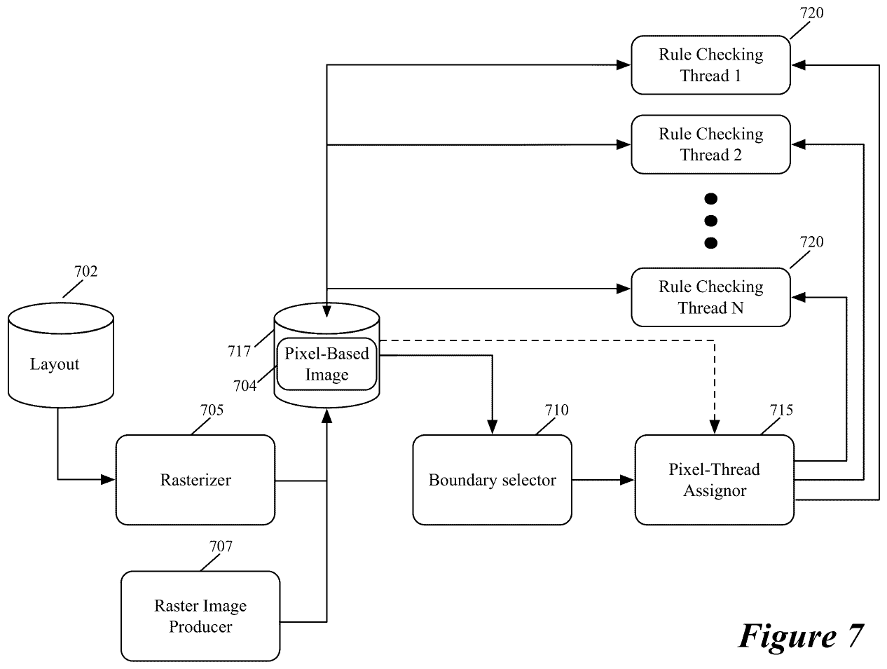

FIG. 7 presents a block diagram that conceptually illustrates several modules that perform the operations of the process 500. These modules include a rasterizer 705, a raster image producer 707, a boundary selector 710, a pixel-thread assignor 715 and several rule checking threads 720. As shown, the rasterizer 705 produces a pixel-based image 704 for a layout 702 that is defined in the contour domain. A raster image producer 707, on the other hand, natively defines the pixel-image layout 704 in the pixel domain. One example of a raster image producer is an ILT-based OPC tool that defines a mask layout in the pixel domain. The pixel-defined layout is stored in the pixel-based image store 717. From the pixel-based image 704, the boundary selector 710 iteratively selects a boundary of each layout shape for rule checking, and selects several pixels on each selected boundary for the pixel-thread assignor 715, which will be described below.

After selecting a boundary of a shape for rule check, the process 500 assigns (at 520) several pixels that lie along the selected boundary to several different rule-check processing threads that execute concurrently on several processing units. In some embodiments, the different processing units are different processing cores of one or more multi-core processors (e.g., of a single computer on which the process 500 executes or of multi-computers on which the different rule-check processing threads execute).

In some embodiments, the pixel-thread assignment operation (at 520) is performed by the pixel-thread assignor 715 of FIG. 7, which after receiving different pixels to process, selects different rule-check thread 720 for different pixels and directs each thread to process its assigned pixel (e.g., by providing the coordinates of the pixel to the thread). In some embodiments, the pixel-based rule checking operations of the process 500 and thread 720 are not performed for just the boundary pixels that lie along the exterior boundaries of shapes in the layout. These embodiments perform the pixel-based rule checking operations for all pixels of the layout. As such, these embodiments do not perform the boundary selection operation 515 nor have the boundary selector 710. As depicted by the dashed line in FIG. 7, the pixel-thread assignor 715 directly selects each pixel in the layout from the pixel-based image store 717.

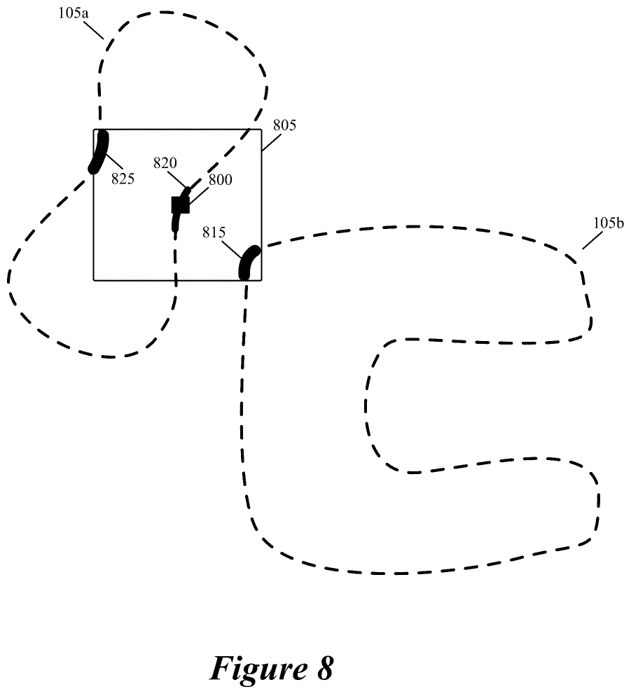

Each pixel-checking thread 720 performs a set of one or more rule checks for the pixel that it is assigned, by examining a region that is defined about the pixel (1) to identify any other nearby boundaries and (2) to perform the set of rule checks for any of the other boundaries that it finds, if any. The examined region in some embodiments is a search window that is defined about the pixel that is assigned to the thread. FIG. 8 illustrates an example of such a search window 805 about a pixel 800 on the right boundary of the shape 105a. This search window captures pixels along the boundary of the shape 105b, as well as pixels on the same boundary of the shape 105a but on its left side.

In some embodiments, the different processing threads that are assigned to several different pixels concurrently execute on several different processing units of one computer or of several computers. The different processing units in some embodiments are different cores of one or more processors, such as CPUs, GPUs, or TPUs. The different processing threads in some embodiments are similar threads and implement a SIMD compute approach for their assigned pixels. The SIMD compute approach is an optimal compute approach for parallel processing one instruction on multiple data sets.

After assigning (at 520) the different pixels to the different threads, the process 500 then uses (at 525) each particular processing thread to identify any other edge pixel that is within a first threshold distance (e.g., defined by the search window) of its assigned pixel and that either is on an edge of another shape or is on an edge on an opposing side of the same shape as the assigned pixel. For each particular edge pixel that is identified to be within the first threshold distance of its assigned pixel (e.g., is identified to be within the search window of its assigned pixel), the processing thread performs (at 530) one or more rule checks to determine whether the identified particular edge violates one or more of the rules. To make this determination at 530, each processing thread in some embodiments dynamically generates the edge on which the identified nearby pixel resides and the edge on which its assigned pixel resides, as further described below.

When the layout is a mask or a design layout, the rule check in some embodiments includes a spacing check and/or a width check. The spacing check ensures that no two edges of two nearby shapes are closer than a threshold spacing distance. For such a check, the nearby edge pixel that a processing thread identifies is on an edge of another shape that is different than the shape of the processing thread's assigned pixel. The width check, on the other hand, ensures that no two edges of one shape are closer than a threshold width distance. For such a check, the nearby edge pixel that a processing thread identifies is on an edge of the same shape of the processing thread's assigned pixel. This edge is on an opposing side of the shape than the processing thread's pixel.

The processing thread in some embodiments determines whether a nearby edge is on the same or different shape than its assigned pixel based on the values of the intervening pixels. For instance, when the pixel values are RTM values between 0 and 1, the processing thread determines whether the intervening pixels between its pixel and the identified edge are 0 or 1. When they are 1, the identified edge is on the same shape, while the identified edge is on a different shape when the intervening pixels are 0. In other embodiments, a separate pixel map is used with a unique integer number assigned to the interior of each region instead of 1. This way, an algorithm can identify edges of the same region by making an explicit check of such integer numbers associated with interior pixels adjacent to the edge pixels.

In FIG. 8, the spacing check would ensure that the pixels that are on the boundary of shape 105b and fall within the search window 805, are not closer than a threshold spacing distance of the pixel 800. After determining that one or more boundary pixels of the shape 105b fall within the search window 805 of the pixel 800, the processing thread of pixel 800 dynamically generates the edge 815 and computes the distance between the pixel 800 and the dynamically generated edge 815. To compute this distance, the processing thread would also dynamically generate an edge 820 on which its pixel resides and then uses both generated edges to compute the distance between them.

The edge-generation processes of some embodiments dynamically generate for a boundary pixel (i.e., a pixel residing on a boundary of a shape in the layout) either a curved edge or a PWL edge formed by one or more straight-line segments. A straight-line segment in some embodiments can be defined by reference to a first-degree polynomial equation, such as y=mx+b, where x and y are coordinates along the line, m is the slope, and b is the y-intercept. A curved edge in some embodiments can be defined by reference to any one of several common ways to define a curve, such as a second degree or higher polynomial equation, a Bezier function, a spline function (B-spline function), etc.

In FIG. 8, the width check in some embodiments ensures that the pixels that are on an opposing side of the same shape 105a and fall within the search window 805, are not closer than a threshold width distance of the pixel 800. After determining that one or more pixels on the opposing boundary of the shape 105a fall within the search window 805 of the pixel 800, the processing thread of pixel 800 dynamically generates the edge 825 and computes the distance between the pixel 800 and the dynamically generated edge 825. To compute this distance, the processing thread would also dynamically generate the edge 820 on which its pixel resides and then use both generated edges to compute the distance between them.

In the above-described examples, a processing thread performs spacing and width checks by computing the distance between (1) its pixel, or its pixel's dynamically generated edge, and (2) the dynamically generated edge of the nearby pixel that falls within its pixel's search window. Rather than dynamically generate the edge(s) and use the edge(s) to compute its spacing and/or width check, the processing thread in other embodiments simply measures the distance between its assigned pixel and any nearby pixel of another shape or of an opposing side of the same shape, that falls within its assigned pixel's search window.

When a processing thread identifies a rule check violation (e.g., a spacing violation or a width violation), the processing thread stores (at 530) a record of this violation in a data store. The data store is a database or another nonvolatile data store in some embodiments, while in other embodiments it is a memory and the record that is stored in this memory is subsequently transferred to a database or another type of nonvolatile data store.

From the database or other nonvolatile data store, the stored violation records (if any) are subsequently retrieved for processing by another program or for presentation to a designer or engineer who is reviewing the layout for rule violations. The presentation is presented in a user interface of a program (e.g., of an MRC or DRC program), or is sent via electronic communication (e.g., email, etc.) as a report. In some embodiments, the IC designer or mask layout engineer can review these violations and make the necessary adjustments to the IC design layout or mask layout to remove these violations. Conjunctively, or alternatively, one or more automated software processes in some embodiments analyze the recorded violations and adjust the circuit design or masks in order to remove these violations.

At 535, the process determines if it has examined all the boundary pixels of the currently selected shape boundary. If not, it returns to 520 to select another batch of boundary pixels and assign them to several processing threads for analyzing (i.e., for performing operations 525 and 530). When the process determines (at 535) that it has examined all the boundary pixels of the currently selected shape boundary, the process determines (at 545) whether it has examined all shape boundaries in the pixelated image. If not, it returns to 515 to select another boundary of another shape, and then repeats operations 520-535 for this shape. When the process determines (at 545) it has examined all the boundaries of all the shapes, the process ends.

As mentioned above, the process 500 does not just examine the boundary pixels but rather examines all the pixels of the layout. As such, the process 500 in these embodiments does not perform the operation 535, and instead determines (at 545) whether it has examined all the pixels of the layout, and if not, returns to 515 to select another pixel of the layout.

For its assigned pixel, each processing thread in some embodiments (1) receives the pixel-based definitions of the shapes, (2) analyzes the pixel-based definitions to dynamically generate any edge that is within a first threshold distance (e.g., specified by a search window) of the particular pixel, and (3) examines each generated edge to determine whether the generated edge violates one or more rules that the thread is checking. For these operations, each processing thread in some embodiments dynamically generates and stores edge data in a volatile runtime memory (e.g., RAM) of its processing unit's computer. In some embodiments, this edge data is subsequently discarded from the volatile memory after the thread has completed its operation for its pixel. The dynamic generation of edges is advantageous as it does not require curvilinear boundaries of layout shapes beforehand to be broken up into a large number of edges that are stored (i.e., have their descriptions stored) on disk for subsequent processing by one or more rule checkers. The edges are dynamically generated by the rule checkers, stored in high speed local memory that is rapidly accessible and discarded once the rule checkers have completed their operations.

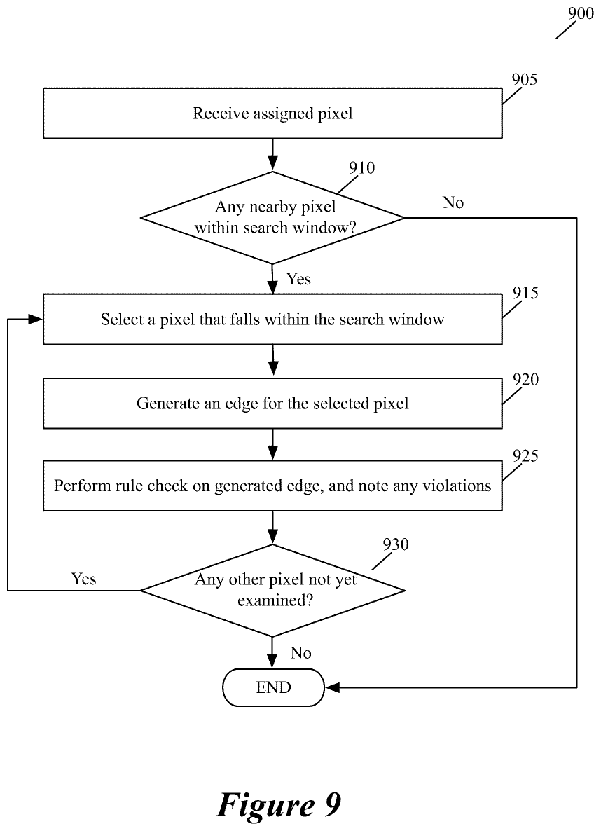

FIG. 9 illustrates a process 900 performed by a pixel processing thread (such as a thread 720 of FIG. 7). As shown, the process 900 starts when it receives (at 905) the identification of a pixel that is assigned to it (e.g., by the pixel-thread assignor 715) for checking. This pixel is along the boundary of a particular shape in some embodiments, while in other embodiments, this pixel can be any pixel in the layout. Next, at 910, the process 900 searches within a search window (e.g., window 805) that is defined about its received pixel to determine whether this window contains boundary pixels of any other shape or the boundary pixels of an opposing side of a boundary on which the received pixel resides. If not, the process ends without identifying any rule check violations.

When the process 900 identifies (at 910) that the search window contains boundary pixels of any other shape or the boundary pixels of an opposing side of the boundary on which the received pixel resides, the process 900 selects (at 915) one pixel that falls within the search window. In FIG. 8, the boundary pixels of shape 105b fall within the window 805 that is defined about the pixel 800.

For the selected pixel, the process 900 then dynamically generates (at 920) an edge. In some embodiments, the process uses a marching-square process to generate the edge for the selected pixel. This marching square process will be further described below. After generating the edge, the process 900 in some embodiments determines (at 920) whether it needs to modify the edge (e.g., modify a straight edge to be a curvilinear edge) so that the edge covers an area that matches pixel values that are assigned (by the rasterization operation) to a region traversed by the edge. When the thread determines that it has to modify the edge, the thread in some embodiments uses the edge to generate a new PWL edge or curved edge (also called curvilinear edge) with the desired coverage area, and then uses this newly generated edge that violates a rule (e.g., a spacing or width spacing rule) enforced by the thread.

At 925, the process then determines whether the generated edge (which may have been modified to match the desired pixel area coverage) is within the second threshold distance of the pixel assigned at 905, or this assigned pixel's edge. When measuring the distance between the generated edge and the assigned pixel's edge, the process 900 in some embodiments also performs a marching square process to dynamically generate the assigned pixel's edge. When a process 900 identifies (at 925) that the generated edge violates one or more rules (e.g., violates a spacing rule or a width rule), the process 900 stores (at 925) a record of this violation in a data store, as described above for operation 530 of FIG. 5.

At 930, the process determines if it has examined all the pixels that fall within the search window. If not, the process returns to 915 to select an unexamined pixel that is along a boundary of another shape than the particular shape of the received pixel, or is on an opposing side of a boundary on which the received pixel resides, and then repeats the operations 920-930 again. The process 900 ends when it determines that it has examined all the boundary pixels that it needs to check.

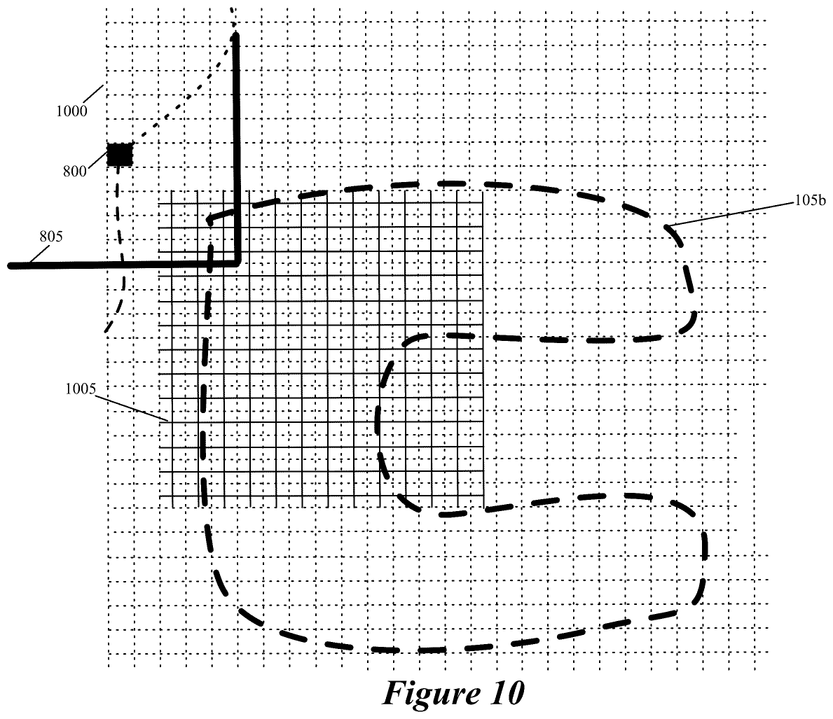

FIGS. 10-12 illustrate several examples of how some embodiments perform the marching square process to dynamically generate an edge for a pixel that falls within a search window. As shown in FIG. 10, these embodiments use a marching square grid (MSG) that is the same size as the pixel grid 1000 of the layout (also called layout pixel grid) but it is offset from the layout pixel grid by half a pixel in the vertical and horizontal directions. In these examples, the layout pixel grid 1000 is depicted with dash lines, while the marching square grid 1005 is depicted with solid lines.

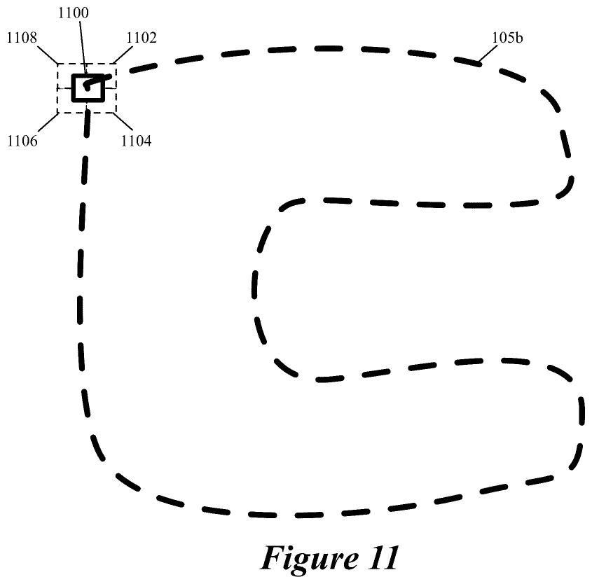

The pixel-dose value for the vertices of each pixel in the MSG 1005 is derived from the values of the four pixels in the layout pixel grid that the MSG pixel overlaps. For instance, to each particular vertex of an MSG pixel, some embodiments assign the pixel dose value of the layout grid pixel that contains the particular vertex. FIG. 11 illustrates one MSG pixel 1100 in the MSG 1005 that overlaps four pixels 1102-1108 in the layout grid 1000. Each of the four vertices of the MSG pixel 1100 is assigned the pixel dose value of one of the four layout-grid pixels 1102-1108 that contains the vertex (i.e., in which the vertex falls).

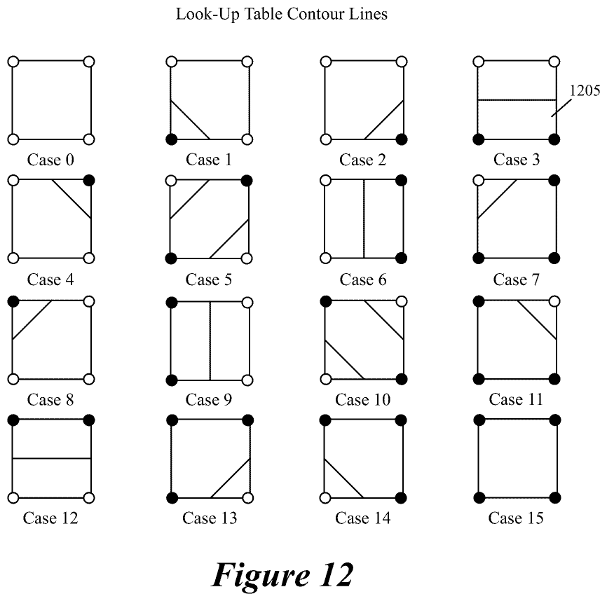

In some embodiments, the pixel dose values of the vertices of an MSG pixel are used to define a marching-square edge through the MSG pixel by using a lookup table (LUT) that associates pixel values of the pixel vertices with pre-defined edges. FIG. 12 illustrates sixteen pre-defined edges that are stored in a LUT to specify the sixteen permutations of zero and non-zero pixel vertex values, with the non-zero vertex values depicted as solid black circles and the zero vertex values depicted as solid white circles. To use the LUT approach, some embodiments perform a thresholding operation to set to 0 or 1 any vertex pixel dose value that is not 0 or 1. Such a thresholding operation will be described further below.

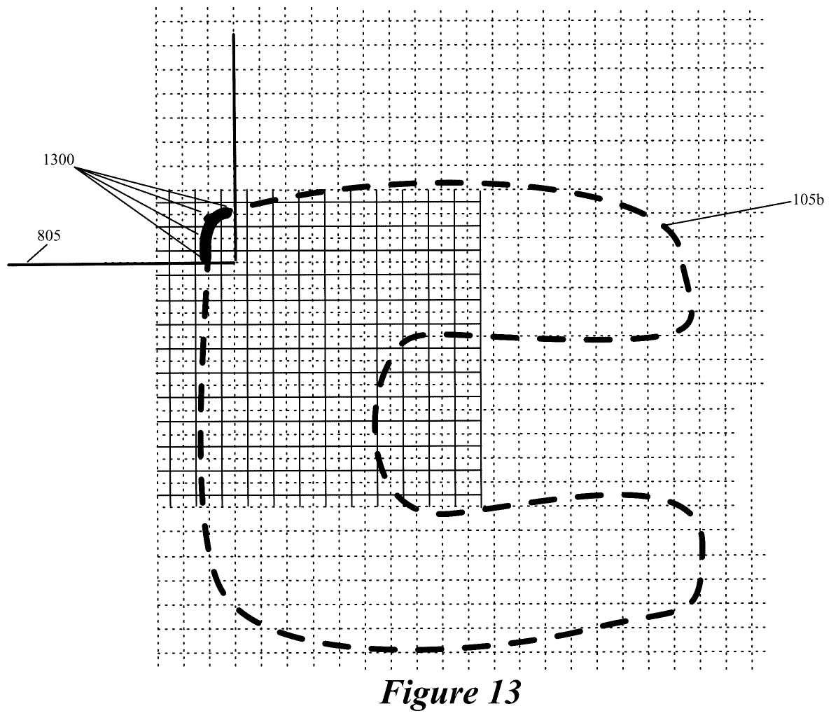

By selecting the particular edge for each MSG pixel within the search window with at least one non-zero vertex value, the implied edge through the MSG pixels that fall within the search window can be generated. FIG. 13 illustrates an example of an implied edge 815 being generated for the corner of shape 105b that falls within the search window 805. This implied edge is made up of four edges 1300 that are defined for the four MSG pixels that fall within this search window. The dynamic-edge generation process of some embodiments can produce different dynamic edges for different MSG pixels that are neighboring MSG pixels along a common boundary of a shape, as further described below.

Several more detailed MRC processes of some embodiments will now be described. One of ordinary skill will realize that these more detailed processes of some embodiments are equally applicable to DRC processes except that the shapes being checked would be shapes in a design layout rather than shapes in a mask layout, and the checked rules are design rules for verifying design layouts rather than mask rules for verifying mask layouts.

Some embodiments operate on sampled geometrical data. In some embodiments, the information content about mask shapes is determined by the pixel size P_{MBM} used in the multi-beam machine. The size of the pixel in some of these embodiments is the spatial sampling period for the geometry. For some of the current mask designs, the P_{MBM} is typically 16 nm-10 nm in mask dimensions, with the wavelength used in EUV lithography being 13.5 nm with the optical system reducing 4× the image of the mask shapes.

The formulated task of the pixel-based MRC of some embodiments is to make sure that whatever the mask shape described by OPC/ILT, it can be written on the mask. Details that are too small or edges with curvature too large cannot be reliably represented when sampled using the grid with spatial period of P_{MBM}. Accordingly, there can be polygons or curvilinear regions that, when rasterized produce the same raster image. The pixel-based MRC of some embodiments is not concerned with those original polygons, but rather examines the raster data in whichever way it was produced. For example, let us take an edge of a region with a curvature radius less than 2*P_{MBM}. Information about this curvature value will be lost in the sampling process and the edge will be effectively aliased as some other edge with a larger curvature radius. From the pixel information, it is not even possible to infer what that original curvature was supposed to be. However, by analyzing the sampled data, it can be determined that the edges are too close. Checking the distance between edges encoded in pixels, checking the areas taken by pixels, and checking the local curvature of edges are the basic building blocks of the pixel-based MRC of some embodiments. These checks are accomplished by using the concepts of “pixel dose equivalence” and “implied edge” discussed above and below.

Many different curves can produce the same pixel value during the rasterization process. When any two given curves are covering the same area of a pixel, those curves are called pixel dose equivalent in these pixels, as discussed in Abhishek Shendre, Aki Fujimura, Mariusz Niewczas, Tom Kronmiller, “You don't need 1 nm contours for curvilinear shapes: Pixel-Based Computing is the Answer,” Proc. SPIE 12293, Photomask Technology 2022, 1229307 (1 Dec. 2022). As many geometries can correspond to the same pixel values, there are many possible contours that can be inferred from the given pixel data. Some embodiments define an implied edge as a smooth curve going through pixels that represent the pixel data accurately as long as the pixel data is generated from a band-limited geometry. A band-limited geometry for a given pixel size can be defined (e.g., rasterized) as geometry data that can be sampled using the pixels without loss of frequency information (e.g., while satisfying the Nyquist-Shannon Sampling condition). Typically, a QTM is a result of sampling the band-limited data whereas the rasterized geometry is not. For the rasterized geometry, some embodiments define the implied edge from the edges defined by the commonly known marching squares procedure.

To process an edge location information from a pixel value, some embodiments choose a curve form that is convenient and devise a way to find an implied edge of that form. For example, a commonly known marching squares process constructs line segments approximating the position of the edge contour. Another method would be to create a complex polynomial approximation of the curved edge passing through each pixel (e.g., B-spline or Bezier curve). In such case, it is sufficient that the polynomial has a degree of two or greater as it is approximating band-limited data.

In some cases, there is not enough information in the sampled data to re-create an arbitrary, detailed curve within each pixel unless one has some prior knowledge about the curve. An example of such prior knowledge would be the knowledge that the original data before rasterization was Manhattan geometry.

Some embodiments generate the implied edges to calculate edge distances when processing the geometrical information in pixel domains. Contrary to the traditional edge-based approach, in the pixel domain algorithm of some embodiments there is no need to preserve generated implied edges for subsequent use. In these embodiments, the implied edges are created on-the-fly as local objects, or even treated as abstract mathematical concepts without any explicit in-memory object representations, used to calculated edge distances, and then discarded when required distance calculations are completed.

Implied edges work because raster image containing band-limited data can be upsampled to represent the edge of the region with arbitrary high accuracy. From Shannon sampling theorem, it is known that there is no information lost when the process samples the band-limited data with a frequency bigger than twice the highest frequency present in the data. Hence, the pixel image inside the multi-beam machine contains very accurate information about the edges of the region even though the accurate locations of edges may not be visible in an obvious way. That accuracy is theoretically limited by the pixel size and can also be practically limited by the process used to create the pixel image.

Note, that if the entire processing flow remains within the pixel domain, the latter limitation becomes irrelevant. However, when the pixel image is created by the rasterization process, the image has to be smoothed by special filters to prevent aliasing if Fourier analysis is applied. With that condition in mind, an arbitrarily fine and accurate pixel image can be obtained by a procedure called Fourier interpolation because it is assumed that the process operates on band-limited data. In short, the image is transformed using 2D discrete Fourier Transform (e.g., 2DFFT algorithm).

Next, in spatial frequency domain, the 2D array representing the transform is extended and values of zero (zero-padding) are inserted for all the new entries that represent higher frequencies. Since the signal is band-limited, that zero-padding expresses without any loss of accuracy that there are no higher frequency terms in the transform. Next, the inverse 2DFFT is applied to this extended data which produces an up-sampled pixel image. Such an up-sampled image can be contoured, for example using the commonly known marching squares algorithm to obtain a high accuracy edge-base description. Some embodiments use the assumption that, without loss of generality, the edge occurs in locations where the values of the pixel map interpolate to 0.5. Some other value of threshold may be assumed in special circumstances, but it does not change how the contouring operation would proceed. The above procedure shows that it is possible to infer very accurate edge location information from the implied curve presented in the image map in the multi-beam machine. Thus, the use of the implied curve is justified and does not lead to any inherent loss of accuracy.

Having established that the processed data in the pixel image is band-limited, and that the implied edge can be defined with an arbitrary accuracy from the pixel image when the initial data is band-limited, the pixel-based MRC of some embodiments can be described. The MRC of some embodiments checks the following three rules (1) no region can be narrower than certain minimum width, (2) the minimum distance between any two regions cannot be smaller than certain minimum spacing, and (3) the minimum area covered by a given region, or minimum area not covered, should be larger than certain minimum area.

The minimum width rule specifies that if the distance between any two pixels with implied curves is less than the minimum width, then the two pixels violate the minimal width violation. Width violation will be ignored if two edge pixels are close to each other along the same implied curve than maxEdgePath. In some embodiments, this internal parameter of the algorithm is set to:

maxEdgePath=0.5*Σ*max(minWidth,minSpacing)

The minimum distance rule check ensures that the distance between any two regions cannot be smaller than certain minSpacing. It means that the distance between any pixels from two regions should not be less than minSpacing. Because the two regions may be connected, the MRC of some embodiments applies the maxEdgePath constraint for these pixels too. The minimum area rule check ensures that the area covered by a given region or minimum area not covered should be larger than a minArea value.

The input to the MRC process of some embodiments includes the rasterized pixel image ImageIn, with a predetermined P_{MBM} in which each pixel has a floating point value Pₐ∈[0.0,1.0] representing the percentage of this pixel covered by the curvilinear mask region. This input also includes values for minWidth, minSpacing, minArea, and required accuracy criteria MaxPlacementError (e.g., P_{MBM}=10 nm, minWidth=25 nm, minSpacing=26 nm, minArea=625 nm², MaxPlacementError=0.05 nm).

For MaxPlacementError, the accuracy with which the width, spacing, and area determine the up-sampling rate. For instance, in some embodiments, the MRC process up-samples by 4×, to create a raster image with a resolution of 2.5 nm for the exemplary numbers mentioned above. This allows the MRC process to find an edge location using the marching square process with an accuracy better than 0.5 nm. In general, large enough upsampling allows for small enough EPE. For these exemplary numbers, four times upsampling was a good enough.

The input image (ImageIn) is then up-sampled by 4× using Fourier interpolation. This results in the up-sampled image (ImageIn4×). From ImageIn and ImageIn4×, the MRC process creates the distance map ImageInD in the following way (1) create ImageInD as a map of the same size as ImageIn by initializing all pixels in ImageInD to the value 2*max (minWidth, minSpacing), and (2) for each pixel in ImageIn, check all pairs of edge-pixels in opposite directions relative to the center of this pixel and select a pair with minimal distance.

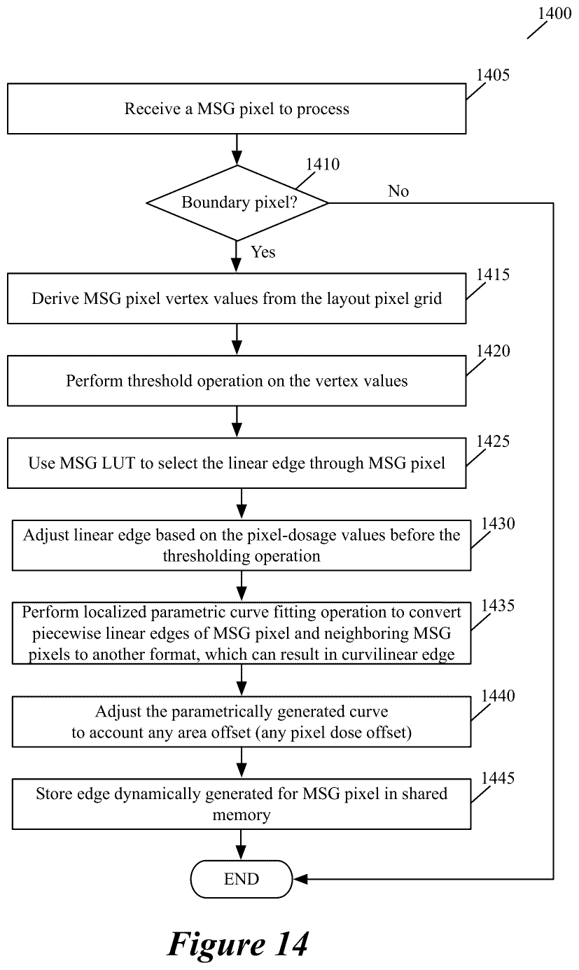

Another example of the pixel-based rule checking of some embodiments will now be described by reference to FIGS. 14-16. In these embodiments, the pixel-based rule checking process divides the layout (e.g., mask layout or design layout) into one or more pixelated regions. For each pixelated region, the process assigns different processing threads to different MSG pixels in the region. Each processing thread then determines whether its assigned MSG pixel is a boundary pixel (i.e., lies along a shape's boundary), and if so, dynamically generates a local edge that runs through its MSG pixel.

After a thread dynamically generates an edge for its associated pixel, the thread stores the generated edge in a memory (e.g., a volatile runtime memory, such as RAM) that is shared among the processing threads. Each processing thread then uses the stored, generated edges to perform pixel-based rule checking for its respective pixel. In some embodiments, the pixel-based rule checking examines spacing rules for non-edge pixels (i.e., pixels that do not lie on an edge of an object in the layout) and edge pixels (i.e., pixels that lie on an edge of an object in the layout). Some embodiments use the same thread to perform the edge-generation process and the rule-check process for an MSG pixel, while other embodiments use different threads to perform this process for an MSG pixel.

FIG. 14 illustrates a process 1400 that a pixel-processing thread performs to dynamically generate a local edge that traverses through its assigned pixel when this pixel lies on a boundary of a shape in the layout. The pixel-processing thread performs the process 1400 in some embodiments each time it is assigned a pixel to process by the pixel-based rule checking process. The process 1400 starts when the thread receives (at 1405) a pixel to process. In some embodiments, the received pixel is an MSG pixel (e.g., pixel 1100 of FIG. 11) defined in an MSG (e.g., MSG 1005 of FIG. 10).

To provide an MSG pixel to each thread, the rule checking process in some embodiments pixelates the layout using a pixel grid and associates a pixel dose value with each pixel in the pixel grid, when the rule checking process does not receive the layout in a pixelated format (e.g., when it receives the layout in a contour domain). In some embodiments, the rule checking process superimposes an MSG over the pixelated layout and then divides the layout into one or more regions to iteratively process. When two or more regions are defined, the rule checking process in some embodiments has the regions overlap so that it can perform rule checking on shapes that are near the boundaries of the regions.

At 1410, the process 1400 determines whether its assigned pixel lies along a boundary of a shape in the layout. In some embodiments, each MSG pixel in some embodiments has four vertices that fall within four pixels of the layout pixel grid that pixelates the layout, as described above by reference to FIGS. 10 and 11. In some of these embodiments, the process 1400 determines that its MSG pixel lies along a shape's boundary when at least one of its vertices falls in a layout-grid pixel that has a pixel dose value associated with a shape's boundary (e.g., has a non-integer pixel dose value between 0 and 1 in the embodiments where exterior and interior pixels are 0 and 1, and boundary pixels are between 0 and 1).

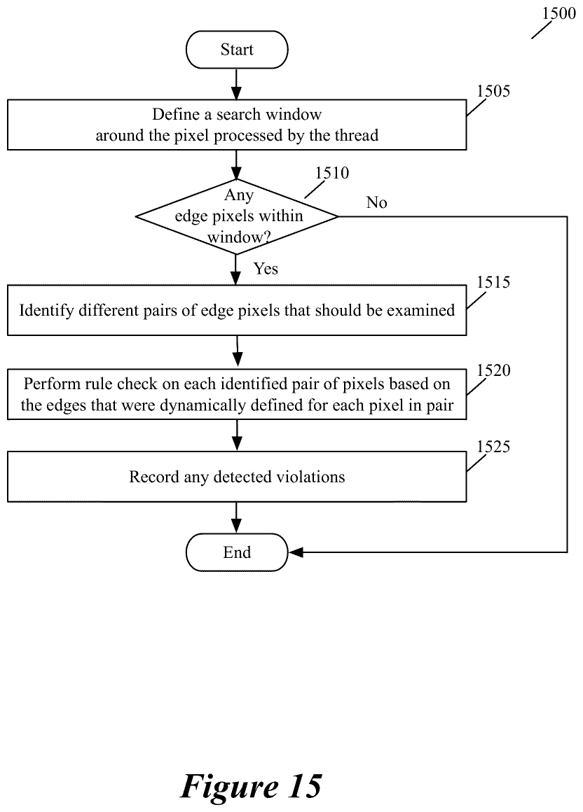

When the process 1400 determines (at 1410) that its assigned MSG pixel does not lie along a layout shape's boundary, the process 1400 ends its edge generation operation. In some embodiments, the thread that performs the edge generation operation for an MSG pixel, also performs a rule checking operation (e.g., the operation described below by reference to FIG. 15) for this MSG pixel once other threads have completed their edge generation operations. In other embodiments, the rule checking process separately assigns threads for the edge-generation and rule-checking operations for each MSG pixel and hence one thread might not perform both of these operations for one MSG pixel in the region being processed.

When the process 1400 determines (at 1410) that its assigned MSG pixel lies along a layout shape's boundary, the process 1400 sets (at 1415) the pixel dose value for each vertex of its MSG pixel to equal the pixel dose value of the pixel in the pixel grid that contains the pixel. For instance, for the MSG pixel 1100 of FIG. 11, the process assigns the pixel dose values of the pixels 1102-1108 to the four vertices of the MSG pixel 1100. In other embodiments, the pixel dose values for the MSG pixel vertices are defined before the process 1400 is called.

Next, at 1420, the process 1400 performs a thresholding operation to assign a 0 or 1 look-up value for each vertex of the MSG pixel. In some embodiments, this thresholding operation compares each vertex's assigned pixel dose value to a threshold value, and then assigns the vertex a look-up value of 1 when the vertex's assigned value equals or exceeds the threshold value, or a look-up value of 0 when the vertex's assigned value is below the threshold value. Other embodiments perform this thresholding operation differently (e.g., assign the vertex a look-up value of 1 when the vertex's assigned value exceeds the threshold value, or a look-up value of 0 when the vertex's assigned value equals or is below the threshold value).

The process 1400 then uses (at 1425) the assigned look-up values of the MSG pixel vertices to perform a look-up in the MSG LUT to identify a PWL edge (formed by one or more straight-line segments) that traverse through the MSG pixel. The above-described FIG. 12 illustrates an example of such a LUT. In this example, the illustrated sixteen pre-defined straight-line edges are defined for sixteen permutations of zero and non-zero pixel vertex values, with the non-zero vertex values depicted as solid black circles and the zero vertex values depicted as solid white circles.

In the LUT example of FIG. 12, each pixel is a square pixel that has four sides, and a straight-line edge that traverses through the MSG pixel intersects two or four sides (pixel edges) of this pixel. At 1430, the process 1400 then performs an interpolation operation (e.g., a linear interpolation operation) to adjust the PWL edge identified at 1425 to more closely match the pixel dose values assigned (at 1415) to the MSG pixel vertices along the intersected sides of the MSG pixel. For instance, assume that the identified PWL edge is edge 1205 in FIG. 12 and that the pixel dose values are 0 and 0.1 for the top left and top-right vertices of the MSG pixel. The interpolation operation of the process 1400 would adjust the identified PWL edge to have a positive slope as it traverses from the left side of the MSG grid to its right side.

At 1435, the process then performs a parametric-curve fitting operation to convert, if necessary, the line segments of the MSG pixels that remains after 1430 into a curvilinear edge through the pixels. The dynamically generated edge through the MSG pixel can be PWL or curvilinear after the parametric-curve fitting operation 1435. The parametric-curve fitting operation 1435 finds the mathematical curve description that fits best in the given region according to some best fit criteria. These criteria can be either minimum total distance from the relevant MSG line segments or cover the same area as the pixel assigned area.

In some embodiments, this parametric-curve fitting operation generates the curvilinear edge for the MSG pixel by examining (1) the pixel dose values of vertices of its assigned MSG pixel, and (2) the line segment identified for this MSG pixel. In other embodiments, this parametric-curve fitting operation generates the curvilinear edge by using (1) the line segment that it identifies for its assigned MSG pixel and (2) the line segments identified for the neighboring MSG pixels that neighbor its assigned MSG pixel in the MSG. In some embodiments, the line segments of the neighboring MSG pixels are identified by the process 1400 by performing the operations 1415-1430 for these neighboring MSG pixels. In other embodiments, these line segments are identified by other threads that (1) process the neighboring MSG pixels (by executing other instances of the process 1400) and (2) store their results in a memory shared with the process 1400. In these embodiments, the process 1400 stores in the shared memory the line segment that it has after its adjustment operation at 1430.

The dynamically generated edge through the MSG pixel can be PWL or curvilinear after the parametric-curve fitting operation 1435. At 1440, the process 1400 then performs an edge-adjustment operation that, if necessary, adjusts the generated edge to more closely match the pixel dose values associated with the processed MSG pixel (i.e., the MSG pixel received at 1405). In some embodiments, this adjustment is just based on the pixel dose values of the pixels that the received MSG pixel overlaps in the pixel grid, while in other embodiments this adjustment is based on the pixel dose values associated with the processed MSG pixel and the MSG pixels that neighbor the processed MSG pixel in the MSG.

At 1445, the process stores the edge that remains after the edge-adjustment operation 1440 in a memory shared with the other pixel-processing threads, and then ends. The generated edge in some embodiments is an edge that only goes through the MSG pixel processed by the process 1400 (i.e., the MSG pixel received at 1405), while in other embodiments, the dynamically generated edge is an edge that the process 1400 generates for its assigned MSG pixel and the MSG pixels that neighbor its assigned MSG pixel in the MSG.

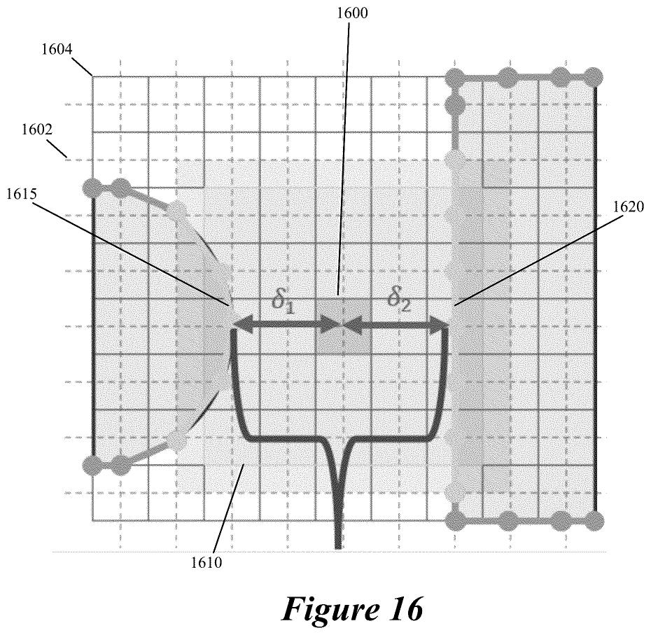

FIG. 15 illustrates the rule checking process 1500 that a thread performs for an MSG pixel that is assigned to it. This process 1500 will be described by reference to the example illustrated in FIG. 16, which shows the spacing rule check being performed for a pixel 1600 in an MSG 1604. In this example, the dotted lines are pixels in the pixel grid 1602 that pixelates a 9×10 pixel region, while the solid lines are marching square pixels.

In some embodiments, the process 1500 is performed for an MSG pixel in a region after all processing threads have dynamically identified and generated edges along the boundaries of one or more shapes in the region and stored the generated edges in a shared memory. At 1505, the process defines a search window about the MSG pixel that it is processing. The search window 1610 in FIG. 16 is a search window that is defined about the MSG pixel 1600.

Next, at 1510, the process 1500 determines whether the search window encompasses two or more MSG pixels for which two or more edges have been dynamically generated. If not, the process 1500 ends as two or more MSG pixels are needed to perform the spacing rule check. On the other hand, when the process determines (at 1510) that the search window encompasses two or more MSG pixels, the process identifies (at 1515) different pairs of MSG boundary pixels to check. Both pixels in each identified pair in some embodiments are pixels that fall within the search window identified at 1505.

In some embodiments, the MSG pixel pairs can be pixel pairs on boundaries of two shapes for which the process 1500 has to perform a spacing check to ensure that the two shapes are far enough apart, or can be pixel pairs on the boundary of one shape for which the process 1500 has to perform a minimum width check. FIG. 16 illustrates a space rule check for two pixels 1615 and 1620 that lie along the boundary of two different shapes, one being a partial circle on the left and the other being a partial rectangle on the right. Also, for this example, the process 1500 would examine all combination of MSG pixel pairs that have one pixel in the search window along the partial circle on the left and one pixel in the search window along the partial rectangle on the right.

After identifying (at 1515) one or more pairs of MSG boundary pixels to check, the process performs (at 1520) its rule check for each identified pair based on two edges that were dynamically generated for each pixel in the pair, in order to identify any rule check violation. For the example of FIG. 16, the process 1500 is shown as checking whether the distance between the two pixels 1615 and 1620 (which is the sum of the distance between the pixel 1600 and each of these two pixels 1615 and 1620) is less than the required minimum spacing distance. Distance between edges can be computed by any of the methods well known from analytical geometry.

At 1525, the process 1500 records in a data store any rule check violations that it identifies at 1520, and then ends. The stored rule check violation in some embodiments identifies the rule that is being violated, the shape or shapes that have violated the rule, and location data that specifies the location of the violation in the layout. In some embodiments, an IC designer or mask layout engineer can later review these violations and make the necessary adjustments to the IC design layout or mask layout to remove these violations. Conjunctively, or alternatively, one or more automated software processes in some embodiments analyze the recorded violations and adjust the circuit design or masks in order to remove these violations.

As described above, some embodiments can have one processing thread that is assigned to one pixel (e.g., pixel 1600) perform a rule-check process 1500 with respect to two edges (e.g., edges 1615 and 1620) that are dynamically generated by two other processing threads (e.g., such as two threads that execute two instances of the process 1400). In other embodiments, however, one processing thread would not only perform the rule check for its assigned pixel but also dynamically generate one or more edges (that traverse through one or more boundary pixels) that the processing thread needs to analyze for the rule check for its assigned pixel.

One advantage of the MRC process of some embodiments is that it can be processed completely on processors (such as GPUs and TPUs) in a massively parallel way with a pixel being a unit of parallelism. The data required by each thread can be kept in shared memory. This means that the data access is very fast. Moreover, the process requires almost no communication between threads what contributes to a very high performance.

The MRC process of some embodiments performs the following operations to check width/space violations using ImageInD. This process uses each blank pixel to check width/spacing violations and stores violation values and pixel pair indices in the corresponding element of a distance map. It also uses each edge pixel to check if its neighbors are also edge pixels and check width/spacing violations for these pairs. If a violation is found, it is stored in a distance map. The distance map allows storage of minimal distance or error values for each width, spacing and area violation. The MRC process of some embodiments propagates error values from blanked pixels to edge pixels by using stored indices to generate error markers. It would also post process error markers to eliminate those for which both edges lie on the edge of length less than maxEdgePath.

Pixel-based area computation in some embodiments is based on summarizing of pixels starting from a pixel inside a region through all neighboring pixels until all neighbors are spaces or minArea is exceeded. For instance, some embodiments compute the area covered by any shape by the pixel dose values of the pixels within the shape and on the boundary of the shape. Similarly, these embodiments compute the area between any two shapes by the inverted pixel dose values of the pixels between the shapes and on the boundary of the shapes. When the computed area of a shape or between shapes is less than minArea, a minimal area violation is found in some embodiments. The minimum area check is also performed in some embodiments to catch a small protruding notch of a shape (i.e., a smaller shape that is part of a bigger shape and protrudes from a larger portion of the bigger shape) that is smaller than the minimum acceptable size for such notches.

Another rule that is enforced by some embodiments is the minimum enclosure spacing rule, which specifies that the minimum spacing for one object (e.g., one metal contact on one layer) to overlap another object (e.g., another metal object on another layer) should exceed a threshold application. Also, as mentioned above, some embodiments also enforce the maximum local edge curvature rule that specifies a maximum allowed curvature for the contour of a shape in the layout. To do this, some embodiments compute the first and second derivatives along the shape's boundary contour, and then use these derivatives to determine whether any curvature along the shape's boundary violates the maximum local edge curvature rule.

For instance, some embodiments dynamically generate the boundary edge of the shape at each boundary pixel of the shape (i.e., at each pixel that lies along the shape's boundary), and then compute the first and second derivatives of each dynamically generated boundary edge. These embodiments then use these derivatives to quantify the slope of the tangent of the boundary edge and the rate of change of this slope. Based on these quantified values, these embodiments then perform a maximum local edge curvature rule check (e.g., by determining whether the rate of change of the slope exceeds a threshold value). When the maximum local edge curvature (e.g., when the rate of change of the slope) exceeds a threshold value, these embodiments determine that the shape has a curved edge that violates the maximum local edge curvature rule.

Many of the rule checks described above and below are used to ensure that shapes on one layer of a layout (e.g., a design layout or a mask layout) comply with one or more rules that are enforced for the layout or that layer of the layout. As mentioned above, examples of such rules include minimum spacing rule, the minimum width rule, the minimum area rule, the maximum curvature rule, etc. Hence, these rules are assessed with respect to shapes on each individual layer of the layout.

Other rules are enforced to assess the relationship between different shapes on different layers of the layout. For an IC with numerous z-axis connections (e.g., via connections) between different IC layers (e.g., different metal layers of the IC), some embodiments enforce a minimum enclosure rule for the IC's layout (e.g., its design layout). This minimum enclosure rule ensures that the via contacts on different layers for each via have sufficient overlap. Some embodiments also enforce this minimum enclosure rule on layouts.

Some embodiments not only detect rule check violations (e.g., MRC or DRC violations) in a layout, but also use automated processes to correct the detected violations. The automated processes of some embodiments only correct detected violations that are smaller than a threshold size as larger violations can require relatively larger changes to the layout, which might be more problematic (e.g., might require changes to items in the layout that have some unwanted side effects on the physical properties of the circuit). Eliminating violations than are smaller than a threshold size can still be very useful as resolving small violations manually can be quite time consuming.

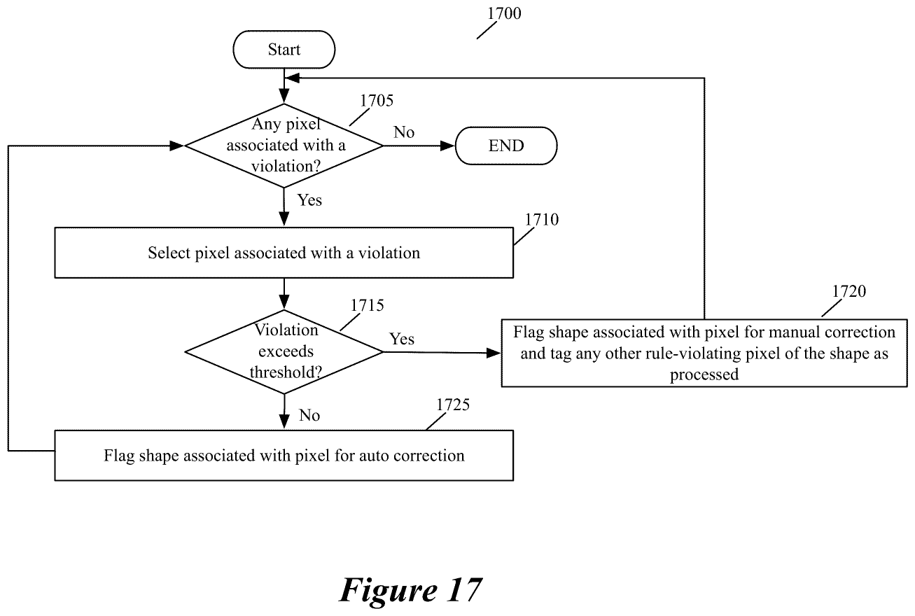

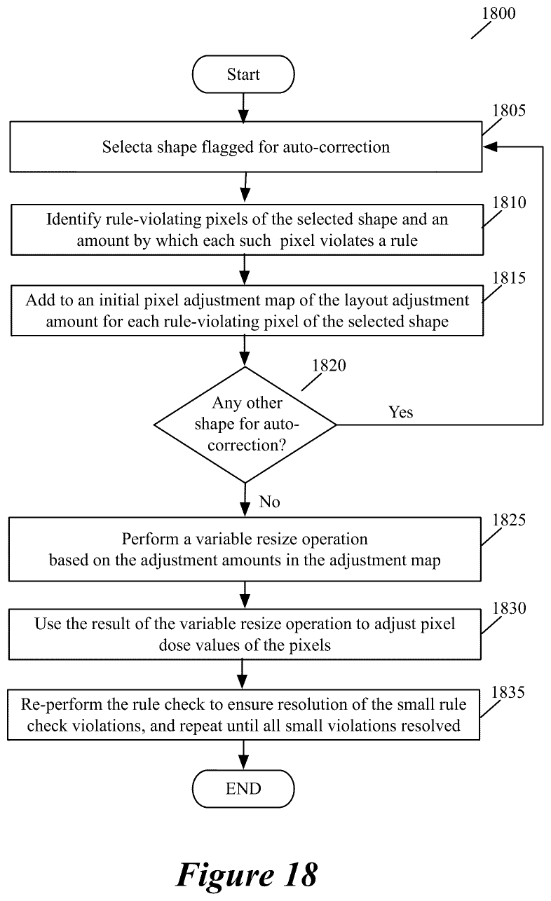

FIG. 17 illustrates a process 1700 that steps through the detected rule-check violations (e.g., DRC or MRC violations) and tags each violation for either manual or automatic correction. The violations that are tagged with automatic correction are then processed by the automated process 1800 of FIG. 18 to correct the violation. The process 1700 initially determines (at 1705) whether any pixel in the pixel-based definition of the layout has been associated with a rule check violation (e.g., at 530, 925 or 1525 of process 500, 900, or 1500). If not, the process ends.

When the process determines (at 1705) that a pixel has been associated with a rule check violation (e.g., a spacing violation, width violation, area violation, curvature violation, etc.), the process selects (at 1710) one such pixel, and then determines (at 1715) whether the violation associated with the selected pixel exceeds a threshold size. When the pixel-rule check process (e.g., process 500, 900, or 1500) of some embodiments performs a rule check for a pixel, the process records an amount that identifies the size of the violation. For instance, for a spacing violation of a first pixel of a first shape, the pixel-rule check process of some embodiments records how much less than the minimum spacing requirement the first pixel's dynamically generated edge is to the edge of a neighboring second shape. Similarly, for a width violation of a first pixel of a first shape, the pixel-rule check process of some embodiments records how much less than the minimum spacing requirement the first pixel's dynamically generated edge is to the other edge of the first shape.

When the process determines (at 1715) that the violation associated with the selected pixel exceeds the threshold size, the process flags (at 1720) the selected pixel's shape (e.g., associates the shape with a first manual-correction value of a flag variable) for manual correction by the layout engineer (e.g., the design layout engineer or mask layout engineer). With this flagging, the process 1700 also records, or maintains a previous recording, that identifies the rule-violating pixels of the flagged shape. Through a user interface (e.g., a graphical user interface) of a layout editor, an engineer subsequently reviews all shapes that are tagged for manual correction along with their rule-violating pixels and provides input for manually modifying the shapes that are flagged for manual correction.

When multiple pixels of a shape are associated with rule-check violations and one of these violations is larger than the threshold size in some embodiments (or larger or equal to the threshold size in other embodiments), the process 1700 flags the shape for manual correction and designates all the other rule-check violations of the pixels of the shape as having been processed by the process 1700, so that no other detected rule-check violation of the shape could be subsequently designated for auto-correction even when the other rule-check violation is smaller than a threshold size. In other embodiments, the process 1700 designates some of the smaller violations (e.g., unrelated violations) of a shape for auto-correction, while designating some of the other violations (e.g., larger violations or smaller violations related to larger violations) for manual correction. From 1720, the process 1700 returns to 1705, and this return will be described further below.

When the process determines (at 1715) that the violation associated with the selected pixel (i.e., the pixel selected in the last iteration of 1705) does not exceed the threshold size in some embodiments (or is smaller or equal to the threshold size in other embodiments), the process flags (at 1720) the shape associated with the selected pixel for auto-correction (e.g., the process associates this shape with a second auto-correct value of a flag variable). The process 1700 in some embodiments can later change this flagging (e.g., change the flag to the first manual-correction value) if it determines in a subsequent iteration that another rule-violating pixel of the shape has a rule violation that exceeds a threshold value. When flagging a shape for auto-correction, the process 1700 also records, or maintains a previous recording, that identifies any rule-violating pixel(s) of the auto-corrected, flagged shape. The process 1800 later uses the identification of the rule-violating pixel(s) to perform its auto-correction operation. From 1725, the process 1700 returns to 1705.

When the process 1700 returns to 1705 from either 1720 or 1725, the process 1700 determines whether there is any other rule-violating pixel in the layout that have not yet been examined by the process 1700 (e.g., selected in a previous iteration through 1710, or designated at 1720 as being examined). The process 1700 ends when it determines (at 1705) that it has examined all rule-violating pixels. Otherwise, the process transitions to 1710 to select another rule-violating pixel that the process 1700 has not yet examined (e.g., has not been selected in a previous iteration through 1710, or has not been designated at 1720 as being examined).

As described above, the process 1700 of some embodiments does not flag a shape for auto-correction when the shape has one or more sections that violate a rule by more than a threshold value even if the shape has one or more sections that violate the rule by less than the threshold amount. Other embodiments, however, flag the shapes differently. For instance, some embodiments flag the sections with the smaller violations (those smaller than the threshold size) for auto-correction, while flagging the sections with the larger violations (those larger than the threshold size) for manual correction.

FIG. 18 illustrates the process 1800 that in an automated manner (e.g., without user input) corrects pixel-rule violations for shapes in a layout that are tagged for automatic correction by the automated process 1700 of FIG. 17. These shapes in some embodiments are layout shapes that only have violations smaller than a threshold size (or smaller or equal to threshold size) as mentioned above. The process 1800 initially performs the operations 1805-1820 to iterate through each layout shape tagged by the process 1700 for auto-correction, in order to generate an adjustment map that identifies an initial set of adjustment values to apply to the contours of the shapes tagged for auto-correction.

Specifically, at 1805, the process 1800 selects a layout shape that has been flagged for auto-correction by the process 1700. Next, at 1810, the process 1800 identifies for the selected shape each pixel (of the shape) that has been identified as violating a layout rule and a rule-violation amount for each pixel that identifies an amount by which the pixel violates the rule. Each rule-checking process in some embodiments identifies for each rule-violating pixel of the shape a rule-violation amount as part of its rule check, after identifying the shape's pixel as violating the rule that it checks. Hence, in these embodiments, the identification at 1810 entails for the selected shape, retrieving from a storage structure (1) the identity of any of the selected shape's pixels that has been tagged as violating a rule, and (2) the amount of this pixel's rule violation.

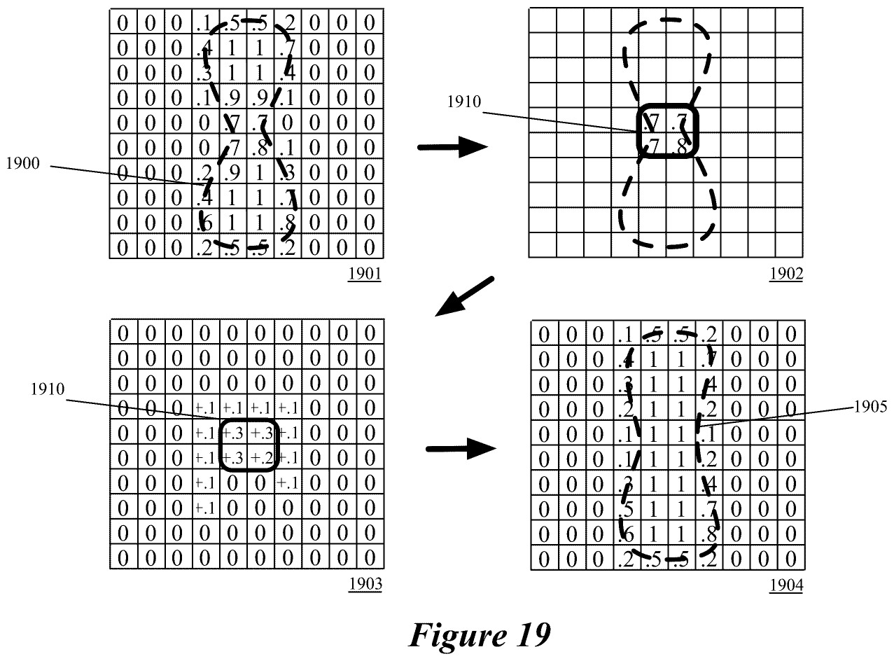

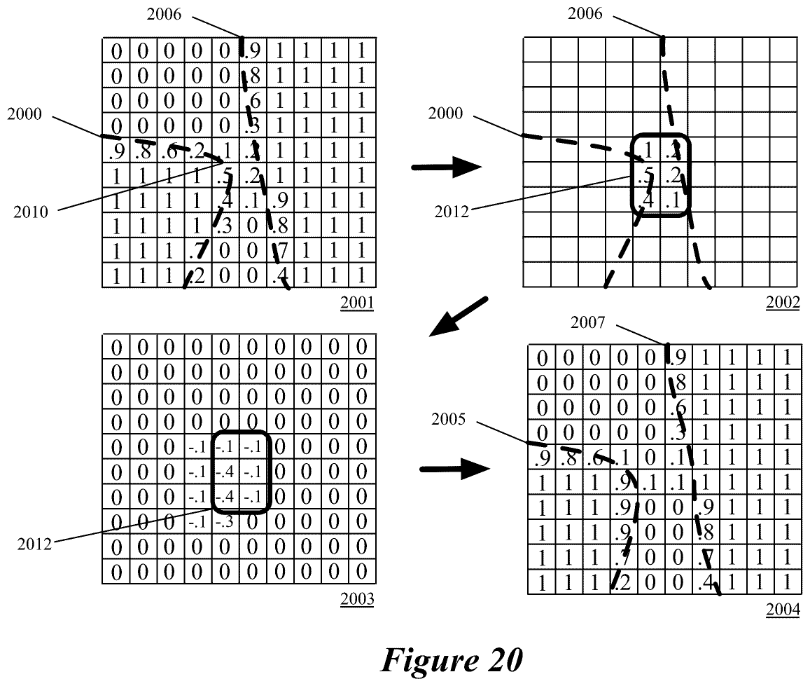

At 1815, the process 1800 adds the violation amounts identified at 1810 for the shape selected at 1805 to an initial adjustment map that specifies adjustment values to the contours of the shape at the pixels that violate the layout rule. In some embodiments, the adjustment value for each rule-violating pixel of the selected shape is just the identified amount of the violation for the pixel, while in other embodiments it is an adjustment value that is derived from the identified violation amount. Examples of the initial adjustment map will be further described below by reference to FIGS. 19 and 20.

As further described below by reference to FIGS. 19 and 20, some embodiments generate one marker to identify each location along a shape that has multiple nearby rule-violating pixels (e.g., multiple neighboring pixels) that are associated with one specific rule violation. These embodiments then adjust the values of all the nearby rule-violating pixels associated with each marker together so that each adjustment for each rule-violating location of a shape can be performed on a per violation basis. In this manner, each such adjustment accounts for the fact that a set of nearby rule-violating pixels that are associated with one marker relate to one single violation as opposed to separately adjusting these pixel values as if they have nothing to do with each other. As further described below, the adjustment in some embodiments to one set of nearby rule-violating pixels that are associated with one rule-violating location on a shape can also modify pixel values of one or more pixels that are near the rule-violating pixel set.

In some embodiments, the adjustment amount (e.g., violation amount) in the adjustment map for each rule-violating pixel of a shape is expressed in terms of a pixel dose value. On the other hand, as further described below by reference to FIGS. 19 and 20, other embodiments express the adjustment amount for each rule-violating pixel of a shape in terms of a length (e.g., in nanometers) by which the contour traversing through the pixel violates the layout rule. To express each adjustment amount (e.g., violation amount) of each rule-violating pixel, some embodiments use the dynamically generated edges to measure the adjustment amount, which in some cases is the violation amount or an amount derived from the violation amount.

At the start of the process 1800, the adjustment map in some embodiments is initialized to specify a default adjustment value of 0 for each pixel of the layout. For each rule-violating pixel of a flagged shape, the process 1800 in some of these embodiments modifies the default adjustment value to a non-default adjustment value when the process 1800 modifies the initial adjustment value at 1815 for the pixel, as mentioned above and further described below by reference to FIGS. 19 and 20. Also, when the layout is a multi-layer layout (e.g., a design layout with one layout for each device or wiring layer), the adjustment map in some embodiments includes one set of map values for each layer of the layout.

Next, at 1820, the process 1800 determines whether it has examined all the layout shapes that have been flagged for auto-correction. If not, it returns to 1805 to select another shape and to perform operations 1810 and 1815 for this shape. When the process determines that it has examined all the layout shapes that have been flagged for auto-correction, the process 1800 performs (at 1825) a variable resize operation based on the adjustment values in the adjustment map to produce one or more adjustment values for (1) each rule-violating pixel of each shape flagged for auto-correction, and possibly (2) one or more non-rule violating pixels that are near one or more rule-violating pixels along the contour of each flagged shape.

In some embodiments, the variable-resize operation produces a set of pixel-dose adjustment values to apply to the pixel dose values of a set of one or more pixel in the layout in order to modify the contours of any shape flagged for auto-correction. For each flagged shape, the adjusted pixel set to which the pixel-dose adjustment set is applied typically includes the rule violating pixels along that shape's contours, and can also include one or more pixels that are not tagged as being rule-violating pixels but are instead near (e.g., are neighbors of) the rule-violating pixels. In some embodiments, this operation specifies adjustment values for the non-rule violating pixels in order to ensure that any adjustment to the contour of any flagged shape (i.e., any shape flagged for auto-correction) is done in such a manner to ensure that the contour has the desired characteristics (e.g., has the desired smoothed characteristic). Examples of the pixel-dose adjustment values produced by a variable-resize operation will be further described below by reference to FIGS. 19 and 20.

Next, at 1830, the process 1800 uses the resulting adjustment values produced by the variable reside operation to modify the pixel dose values of the pixels that form the layout in the pixelated representation of the layout. The operation 1830 in some embodiments involves adding any adjustment value that is produced by the variable resize operation at 1825 for a pixel to the pixel dose value of that pixel. Even though the operations 1825 and 1830 are two distinct operations in some embodiments, these operations are conjunctively performed as one operation in other embodiments.

For instance, in some embodiments, the process 1800 performs for each flagged shape (i.e., each shape flagged for auto correction) a curve fitting operation that uses the pixel dose values of each rule-violating pixel along with the adjustment value computed for this pixel at 1810 (e.g., the rule-violating amount or a value derived from the rule-violating amount). This curve fitting operation adjusts the pixel dose values of any rule-violating pixel, and at times adjusts one or more pixels that neighbor the rule-violating pixel, to auto-correct any shape flagged for auto-correction. This curve fitting operation is a single operation that implicitly performs both the operations 1825 and 1830 in these embodiments.

After modifying the pixel dose values at 1830, the process 1800 then initiates (at 1835) a set of one or more rule-checking processes (such as process 500, 900 or 1500) to re-check the modified layout, and then ends. The set of rule-checking processes is initiated to determine whether the correction to the flagged shapes has resolved the issues with respect to these shapes and/or has not created other rule check violations with respect to other shapes in the layout.

After performing this re-check, some embodiments repeat processes 1700 and 1800 to identify smaller violations and auto-correct these smaller violations. Some embodiments perform two or more iterations of (1) the rule-violation check processes (such as process 500, 900 or 1500) and then (2) the auto-correction processes 1700 and 1800, before ending these iterations and flagging the smaller violations that cannot be fixed for a layout engineer to view. After 1835, the process ends.

FIG. 19 illustrates an example of auto-correcting a shape that violates a minimum width rule. This figure illustrates the example in four operation stages 1901-1904. The first operation stage shows the pixel dose map of the shape 1900 that looks like a figure eight. In this pixel dose map, pixels that are completely within the shape have a dose value of 1, pixels that are completely out of the shape have a dose value of 0, and pixels that are on the boundary of the shape have a dose value between 0 and 1 depending on how much of the pixel is within the shape.

The second stage 1902 illustrates that at the centermost region 1910 of the shape 190, the two opposing sides of the shape are too close to each other such that the shape 1900 violates the minimum width rule. In some embodiments, the minimum width rule is checked for all portions of the shape that are a required threshold distance away from any protruding tip of the shape. The protruding tips of the shape 1900 in this example are the top and bottom parts of this shape. In this example, no two dynamically generated edges for two pixels on opposing sides of a shape should be closer than 1.8 pixels to each other when the two edges are not part of a protruding tip.

The centermost region 1910 includes four pixels that violate this minimum width limit. In other words, the shape's contour that traverses through these four pixels is too narrow at this region. The auto-correction process of some embodiments defines one marker for the centermost region 1910 to identify it as one location along the shape 1900 that violates one of the layout rules. The four pixels in the centermost region 1910 are associated with this marker. The values of these four pixels as well as the values of several nearby pixels are adjusted conjunctively to resolve this one rule violation as further described below.

The auto-correction process of some embodiments computes an initial adjustment value for each of the four pixels in the centermost region 1910 in the adjustment map that it computes at 1815. In the adjustment map, the adjustment value for each such pixel in some embodiments is expressed in terms of a length (e.g., in nanometers) by which the contour traversing through the pixel violates the layout rule. In some embodiments, the adjustment value in the adjustment map for each of the four pixels in the centermost region 1910 is the violation amount or an amount derived from the violation amount. For instance, for the four rule-violating pixels in the centermost region 1910, the auto-correction process in some embodiments computes adjustment amounts that are 0.1 or 0.2 of a pixel length.

After identifying the marker for the centermost region 1910, the auto-correction process of some embodiments then performs a curve-fitting operation that uses the original pixel dose values shown in the first stage 1901 and the adjustment amounts (in the adjustment map) computed for the rule-violating pixels identified in the second stage 1902 to produce a set of pixel-dose adjustment values shown in the third stage 1903. To compute the adjustment values, the auto-correction process in some embodiments uses the inverse of the function that it uses to map the dose values to the location of a shape's contour through the pixels (i.e., uses a function that maps location of a shape's contour to the pixel dose values). To solve this inverse function, different embodiments use different solving processes, such as a local gradient search process or a nonlinear optimization process.

After computing the pixel-dose adjustment values, these adjustment values are then added to the pixel-dose value of the shape 1900 to obtain a modified shape 1905 that is shown in the fourth stage 1904. This curve fitting operation is a variable resize operation as it can specify different pixel-dose adjustment values for different pixels. The modified shape 1905 no longer has any pair of opposing segments that are the required threshold away from any protruding tip of the shape and that are closer than the minimum width amount of 1.8 pixels. As shown in the third stage 1903, the pixel-dose adjustment values not only include adjustment values for the four rule-violating pixels in the region 1910 but also include adjustment values for a certain number of neighboring pixels arounds these four rule-violating pixels.

The pixel-dose adjustment values of these neighboring pixels as well as the pixel-dose adjustment values of the rule-violating pixels ensures that the modified shape 1905 has the desired contour characteristics (e.g., smooth contour). In other words, the curve fitting operation of some embodiments ensures that the auto-correction does not introduce undesirable contours in the auto-corrected shapes (e.g., does not create shapes with jagged edges). Some of the computed pixel-dose adjustment values move the contour of the shape from one pixel to another pixel (e.g., by changing to 1 the dose value of a pixel that previously had a fractional dose value, changing to a fractional value the dose value of a pixel that previously had a 0 dose value, etc.).

The curve-fitting operation of some embodiments that is illustrated in FIG. 19 first produces pixel-dose adjustment values based on the original pixel dose values and the adjustment amounts specified by the adjustment map, and then adds the produced pixel-dose adjustment values to the original pixel dose values. In other embodiments, however, the curve-fitting operation does not first produce pixel-dose adjustment values that are then added to the original pixel dose values. These embodiments directly produce the modified pixel dose values of the modified shape by using the original pixel dose values of the shape along with the adjustment amounts specified in the adjustment map for the rule-violating pixels identified by the rule-checking process. Under this curve-fitting approach, the pixel-dose adjustment values are implicitly computed and applied to the pixel dose values of the original shape to produce the modified shape as part of the curve-fitting operation. In addition, the curve-fitting operation of these embodiments also ensures that the modification to the shape does not introduce undesirable contour characteristics for the shapes (e.g., ensures that the shape has smooth edges).

FIG. 20 illustrates an example of auto-correcting a shape that violates a minimum spacing rule. This figure illustrates the example in four operation stages 2001-2004. The first operation stage shows the pixel dose map that includes portions of two shapes 2000 and 2006. In this pixel dose map, pixels that are completely within a shape have a dose value of 1, pixels that are completely out of a shape have a dose value of 0, and pixels that are on the boundary of a shape have a dose value between 0 and 1 depending on how much of the pixel is within the shape.

At a bend 2010 of the shape 2000, the shape 2000 and the shape 2006 are too close to each other such that these two shapes violate the minimum spacing rule. In some embodiments, the minimum spacing rule is checked for each pixel along the boundary of each shape, while in other embodiments the minimum spacing rule is checked for each pixel in the pixel dose map as described above.

When two shapes are determined to be too close to each other, the spacing rule-check process of some embodiments flags both shapes as violating the spacing check and identifies the pixels of each shape that violate the spacing check. When two shapes are deemed to be too close to each other by a certain amount X, the rule-checking process in some embodiments assigns half of the amount X as the violation amount to each of the two shapes. In other embodiments, the rule-checking process uses other heuristics to distribute the violation amount X between the two rule-violating shapes.

The second stage 2002 illustrates a layout region 2012 that includes six pixels along the boundary of the two shapes 2000 and 2006 that have been identified as violating the spacing rule that specifies a minimum spacing between contours of two different shapes. In this example, no two dynamically generated edges that traverse through the boundaries of two nearby shapes should be closer than 2 pixels to each other. The six rule-violating pixels shown in the second stage 2002 have violation amounts between 0.1 to 0.4 pixels.

In some embodiments, the auto-correction process 1800 specifies these violation amounts or values derived from these amounts as length adjustment amounts in the adjustment map specified at 1815. Also, the auto-correction process 1800 of some embodiments defines one marker for the region 2012 to identify it as one layout region that includes two sections of the two shapes 2000 and 2006 that violate the spacing rule, and associates the six pixels in the region 2012 with this marker. The values of these six pixels as well as the values of several nearby pixels are then adjusted conjunctively to resolve this one rule violation as further described below. In other embodiments, the auto-correction process 1800 defines two different markers for each identified spacing violation, with one marker (1) being defined along the border of each shape 2000 or 2006 and (2) associated with the identified rule-violating pixels of its shape for its associated spacing violation.

The auto-correction process of some embodiments performs a curve-fitting operation that uses the original pixel dose values shown in the first stage 2001 and the adjustment amounts (in the adjustment map) identified for the pixels in the region 2012 illustrated in the second stage 2002 to compute pixel-dose adjustment values shown in the third stage 2003. To compute the adjustment values, the auto-correction process in some embodiments uses the inverse of the function that it uses to map the dose values to the location of a shape's contour through the pixels (i.e., uses a function that maps location of a shape's contour to the pixel dose values). To solve this inverse function, different embodiments use different solving processes, such as a local gradient search process or a nonlinear optimization process.

After computing pixel-dose adjustment values, the computed pixel-dose adjustment values are then added to the original pixel-dose values of the first stage 2001 to obtain two modified shapes 2005 and 2007 that are shown in the fourth stage 2004. This curve fitting operation is a variable resize operation as it can specify different pixel-dose adjustment values for different pixels.

The contours of the modified shapes 2005 and 2007 are no longer within two pixels of each other at any location along the contours. As shown in the third stage 2003, the pixel-dose adjustment values not only include pixel-dose adjustment values to modify the pixel dose values of the six rule-violating pixels in the region 2012 but also includes pixel-dose adjustment values that modify the pixel dose values for a certain number of neighboring pixels around these six rule-violating pixels.

The pixel-dose adjustment values of these neighboring pixels as well as the pixel-dose adjustment values of the rule-violating pixels ensures that the modified shapes 2005 and 2007 have the desired contour characteristics (e.g., smooth contour). In other words, the curve fitting operation of some embodiments ensures that the auto-correction does not introduce undesirable contours in the auto-corrected shapes (e.g., does not create shapes with jagged edges). Some of the computed pixel-dose adjustment values move the contour of a shape from one pixel to another pixel (e.g., by changing to 1 the dose value of a pixel that previously had a fractional dose value, changing to a fractional value the dose value of a pixel that previously had a 0 dose value, etc.).

The curve-fitting operation of some embodiments that is illustrated in FIG. 20 first produces pixel-dose adjustment values based on the original pixel dose values and the adjustment amounts specified by the adjustment map, and then adds the produced pixel-dose adjustment values to the original pixel dose values. In other embodiments, however, the curve-fitting operation does not first produce pixel-dose adjustment values that are then added to the original pixel dose values. These embodiments directly produce the modified pixel dose values of the modified shapes by using the original pixel dose values with the identified adjustment amounts specified in the adjustment map for the rule-violating pixels identified by the rule-checking process. Under this curve-fitting approach, the pixel-dose adjustment values are implicitly computed and applied to the pixel dose values of the original shapes to produce the modified shapes as part of the curve-fitting operation. In addition, the curve-fitting operation of these embodiments also ensures that the modification to the shapes do not introduce undesirable contour characteristics for the shapes (e.g., ensures that the shape has smooth edges).

In the examples illustrates in FIGS. 19 and 20, the pixel dose maps are RTM dose maps in which the pixel dose values are directly related to how much of the pixel is covered by a shape. As mentioned above, other embodiments use CTM and QTM dose map values in which the pixel dose values are indirectly related to how much of the pixel is covered by a shape (e.g., through the use of a function that maps the dose values to the pixels).

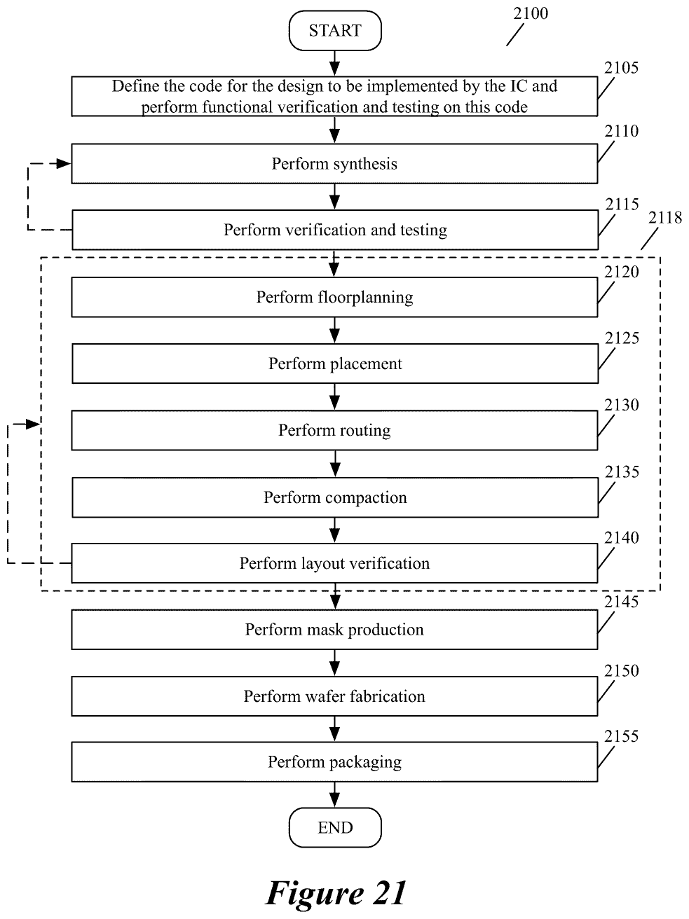

Design rule check and mask rule check are two steps that are commonly performed in the overall process to design and manufacture an IC. FIG. 21 conceptually illustrates an example of one such process for designing and manufacturing an IC. The process 2100 of this figure uses the pixel-based design and mask rule check operations described above to ensure that the design layouts and mask layouts produces by the process do not violate one or more design rules and mask rules.

The process 2100 begins (at 2105) by defining the code that specifies the IC design and performing functional verification and testing on this code. In some embodiments, the process uses one of the common hardware description languages (HDL) to specify the code. The HDL code in some embodiments describes the desired structure, behavior, and timing of the IC. To perform functional verification and testing on the code for the IC, some embodiments specify one or more modules and/or circuit components in the code and check the specified modules and/or circuit components for functional accuracy.

Next, the process 2100 performs (at 2110) a synthesis operation, which converts the HDL description into a circuit representation that commonly includes digital circuit components, such as logic gates, flip-flops, and other larger digital components (e.g., adders, multipliers, etc.). The synthesis operation is typically performed by a synthesis tool.

At 2115, the process 2100 performs verification and testing on the circuit representation that is produced by the synthesis operation. In some embodiments, the verification and testing checks the circuit representation to determine whether this representation meets desired timing constraints and satisfies any other constraint of the HDL code. When the verification and testing fails (e.g., if a portion of the circuit representation fails to meet a constraint), the process 2100 returns to step 2110 (as denoted by a dashed arrow line) to reperform synthesis to modify the circuit representation to resolve this failure.

When the verification and testing at 2115 passes, the process 2100 performs a set of physical design operations 2118, which include operations 2120-2135 between which the process 2100 can iterate through multiple times as further described below. At 2120, the process 2100 performs a floor planning operation that defines a general location for some or all of the circuit blocks (e.g., for various large circuit blocks). For instance, in some embodiments, floor planning divides the design layout into one or more sections devoted to different purposes (e.g., ALU, memory, decoding, etc.), and assigns some or all of the circuit blocks to these sections based on the purposes served by these blocks.

At 2125, the process 2100 performs a placement operation, which is based on the floor planning data and defines a specific location and orientation in the design layout for each circuit block. The placement operation in some embodiments is an automated process that tries to find an optimal placement for each circuit block based on one or more optimization criteria, such as congestion or estimated length of interconnects (e.g., metal wires) needed for connecting the nets associated with the circuit blocks. A net in some embodiments includes a set of two or more pins of one or more circuit blocks that need to be connected electrically (e.g., through a set of wires, contacts, and/or vias). After performing the placement operation, the process 2100 might return to the floor planning operation if it determines that the floor planning should be revised to improve the result of the placement operation.

Once the placement operation is completed satisfactorily, the process performs (at 2130) a routing operation to define the route needed to connect each net (i.e., to connect each set of pins that needs to be interconnected). Each defined route includes one or more interconnect segments (also called wire segments) that traverse one or more interconnect layers (also called wiring layers), and one or more vias and/or contacts that connect pins and/or wire segments on different wiring layers.

To define the routes, some embodiments divide the routing operation into a global routing operation and a detailed routing operation. For each net, global routing defines a global route that more generally defines the route for the net (e.g., defines a general area in the design layout traversed by the route). For instance, in some embodiments, the global router divides an IC into individual global routing areas, called Gcells. Then, a global route (Groute) is created for each net by listing the global routing areas (the Gcells) that the Groute for the net should pass through.

The detailed routing defines the actual route for each net (e.g., the route that connects the set of pins that forms the net). As mentioned above, each defined route includes one or more interconnect segments that traverse one or more interconnect layers, and one or more vias and/or contacts that connect pins and/or wire segments on different interconnect layers. In performing its detailed routing operation, the detailed router of some embodiments uses the global router's Groute data, e.g., by biasing its detail route search for the net to the Groute regions traversed by the Groute defined by the global router.

During or after the detailed routing operation, the process 2100 in some embodiments performs a DRC operation to ensure that the defined routes do not violate design rules. In some embodiments, the process 2100 uses the above-described pixel-based DRC operations to perform one or more of its design rule checks on each defined route. One example of the design rule check that is done for a route is to ensure that the route is not closer than an acceptable minimum spacing requirement on each layer traversed by the route to another route or another component in the design layout on that layer. Routes that violate minimum spacing constraints can cause undue capacitance and in some cases electrical shorts on the IC.

The process 2100 in some embodiments can iterate through the global and detailed routing multiple times to identify better Groutes for some nets in order to improve the detailed routes for these nets or other nets. Also, the process 2100 in some embodiments can return from either of these routing operations to an earlier operation in the EDA flow (e.g., to the placement operation) in order to improve the results of this earlier operation to improve the routes defined by the later routing operation.

After routing, the process 2100 performs (at 2135) compaction operations. In some embodiments, the compaction operation compresses the design layout in one or more directions to decrease the size of the IC die (e.g., to decrease the two-dimensional area of the IC die) that would be manufactured based on the design layout. Reducing the size of the IC improves the performance of the IC in some embodiments. A compacted design layout also lowers costs of the ICs manufactured using the design layout by allowing more ICs to be produced for a given wafer size.

After the compaction operation, the process 2100 performs a layout verification operation (at 2140) to ensure that the compacted design layout (e.g., the compacted routes in this design) to ensure that the layout meets one or more verification criteria. This verification operation includes a DRC operation that ensures that the compacted design layout does not violate design rules. In some embodiments, the process 2100 uses the above-described pixel-based DRC operations to perform one or more of its design rule checks on different items in the design layout (e.g., on the routes, the pins and other components of the design layout).

One example of the design rule check that is done for a route is to ensure that the route is not closer than an acceptable minimum spacing requirement on each layer traversed by the route to another route or another component in the design layout on that layer. Other examples of the design rule check include performing minimum area, minimum width, and maximum curvature of shapes (e.g., routes, pins, contacts, vias, or other components) of items in the design layout, as described above.

The layout verification in some embodiments includes other operations, such as extraction. Extraction in some embodiments computes parasitic values (e.g., parasitic capacitance values or parasitic inductance values) exerted on items (e.g., wire segments) in the design layout. In some embodiments, the extraction operation computes capacitance coefficients for one or more conductive components in the design layout (e.g., for each wire segment of a route, or for the entirety of each route, in the design layout), and uses the capacitance coefficients to compute parasitic influence (e.g., capacitance, resistance, or inductance) on the conductive component(s).

After the compaction operation at 2135 or the subsequent verification operation 2140, the process 2100 in some embodiments can return to an earlier operation in the EDA flow (e.g., to the placement operation, to the global routing operation, or to the detailed routing operation) in order to improve the results of this earlier operation to improve the compacted design defined by the later compaction operation. For instance, when the design is not verified at 2140 (e.g., if a problem with the design is detected during verification), the process 2100 returns to an earlier physical design operation 2120 to 2135 to reperform this physical design operation, and any subsequent physical design operation, for a portion or for the entire design layout. In some embodiments, the design layout that exists after the compaction operation and that passes the subsequent verification operation 2140 on this layout is the end result of the physical design process, is called the physical design layout, and is used as the input to the subsequent operations 2145-2155 that form the manufacturing sub-process of the process 2100.

In some embodiments, the physical design sub-process includes other operations that are not displayed in FIG. 21. These other operations are not displayed for purposes of brevity. Examples of such operations include partitioning, power planning, and clock tree synthesis (CTS). In some embodiments, partitioning divides the design layout into similar-sized subsets and ensures a minimum number of connections between subsections. Power planning defines the power delivery network (PDN) that includes the interconnects for delivery power from the power supply circuit to circuits defined by the IC design layout. CTS in some embodiments defines a clock delivery network for delivering one or more clock signals to circuits defined by the IC design layout. CTS in some embodiments also inserts buffers and/or inverters along the clock signal paths on the clock delivery network in order to balance the load, and decrease or eliminate any clock skew or delay.

The manufacturing sub-process includes a mask production operation (at 2145) that is performed in some embodiments once the physical design verification operation (at 2140) is performed and the physical design layout is verified to pass the one or more verification criteria. In some embodiments, mask production includes mask layout generation, mask simulation, and wafer simulation. Mask layout generation defines the mask layout using commonly known techniques, such as OPC (optical proximity correction) and/or ILT (inverse lithography technology) operations.

During or after the mask layout generation, the process 2100 performs an MRC operation to ensure that the shapes defined in the mask layout do not violate MRC rules. In some embodiments, the process 2100 uses the above-described pixel-based MRC operations to perform one or more of its MRC rules checks on each shape in the mask layout. Examples of the MRC rules include minimum spacing, minimum width, maximum curvature, and minimum area for shapes in the mask layout.

The mask simulation operation simulates the production of the mask using the generated mask layout. Mask simulation includes operations such as mask data preparation (MDP) and Mask Process Correction (MPC) in some embodiments. MDP in some embodiments prepares the mask layout for a mask writer. This operation in some embodiments includes “fracturing” the data into trapezoids, rectangles, or triangles. MPC in some embodiments geometrically modifies the shapes and/or assigns doses to the shapes to make the resulting shapes on the mask closer to the desired shape. MDP may use as input the generated mask layout or the results of MPC. MPC may be performed as part of a fracturing or other MDP operation. Other corrections may also be performed as part of fracturing or other MDP operations. Also, in some embodiments, the mask simulation operation calculates several possible mask images by using charged particle beam simulation.

The wafer simulation operation in some embodiments calculates possible patterns that would be produced on the manufactured IC by using the masks that would be generated based on the mask layout. In some embodiments, the wafer simulation operation includes a lithography simulation that uses the calculated mask images. Additional description of the mask generation, mask simulation, and wafer simulation operations is provided in U.S. Pat. No. 8,719,739, entitled “Method and System for Forming Patterns Using Charged Particle Beam Lithography”, which is incorporated herein by reference.

After the wafer simulation is performed for a given mask layout, the produced wafer patterns are examined to determine whether the mask layout should be revised and/or to determine whether one or more physical design operations should be repeated in order to revise the physical design layout. In some embodiments, the wafer pattern examination involves comparing the produced simulated wafer pattern to an ideal target pattern (e.g., to ensure that the predicted wafer image is within a minimum deviation of the target wafer image).

Conjunctively, or alternatively, this examination involves performing DRC checks (such as the above-described pixel-based DRC checks) on the produced wafer patterns that are predicted to appear on the IC die by the wafer simulator. In some embodiments, the process 2100 can iteratively repeat the sub-operations (i.e., the mask layout generation, the mask simulation, and the wafer simulation) of the mask production operation 2145 in order to improve the quality of the overall generated mask, or can return to one of the earlier physical design operation 2118, as described above.

Once the mask layout is generated and verified, the process 2100 generates the masks specified for all the layers of the IC based on the mask layout. Mask generation transforms each mask image (also referred to as a mask layer, in some embodiments) of the mask layout into one or more lithographic masks in some embodiments. Once the masks are generated, the process 2100 performs (at 2150) wafer fabrication, which uses the generated masks to manufacture multiple IC dies on an IC wafer (e.g., a silicon wafer). The masks for the substrate and each wiring layer are used to generate the devices and wiring on the substrate and each wiring layer of each IC die. Each IC die is usually tested. During the testing of the IC dies, if it is determined that the IC has a defect because of its design or its masks, the process 2100 has to return to an earlier operation to improve its design layout, its mask layout, or its mask production operation. Lastly, the process 2100 performs (at 2155) packaging, which places each IC die in one chip package. Packaging in some embodiments includes slicing a wafer into multiple IC dies and placing each die on a substrate, which is then encapsulated to form a chip package. After performing packaging, the process 2100 ends.

Although several embodiments were described above by reference to performing pixel-based rule checks on design layouts and/or mask layouts used to design and/or manufacture an IC, one of ordinary skill will realize that other embodiments are used to perform pixel-based rule checks for design and mask layouts that are created for designing and manufacturing silicon interposers (e.g., wiring patterns on silicon interposers).

Still other embodiments are used to design and manufacture other patterns on other types of substrates. For instance, some embodiments use the above-described pixel-based rule processes to check the design layouts for designing, and/or the mask layouts for manufacturing, displays such as flat-panel displays (e.g., monitors, televisions, glasses, etc.) or curved displays (e.g., displays for virtual reality or augmented reality headsets). Such design layouts define patterns of controllable pixels on a display substrate, while such mask layouts define masks that can be used to deploy such patterns of controllable pixels on the display substrate.

Still other embodiments use the above-described pixel-based rule processes to check the design layouts for designing other patterns of other elements for other substrates and/or mask layouts for deploying these other patterns of other elements on such other substrates. Examples of such other substrates includes substrates used to manufacture micro-electromechanical systems (MEMS) and other such similar devices.

Many of the above-described features and applications are implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Examples of computer readable media include, but are not limited to, CD-ROMs, flash drives, RAM chips, hard drives, EPROMs, etc. The computer readable media does not include carrier waves and electronic signals passing wirelessly or over wired connections.

In this specification, the term “software” is meant to include firmware residing in read-only memory or applications stored in magnetic storage, which can be read into memory for processing by a processor. Also, in some embodiments, multiple software inventions can be implemented as sub-parts of a larger program while remaining distinct software inventions. In some embodiments, multiple software inventions can also be implemented as separate programs. Finally, any combination of separate programs that together implement a software invention described here is within the scope of the invention. In some embodiments, the software programs, when installed to operate on one or more electronic systems, define one or more specific machine implementations that execute and perform the operations of the software programs.

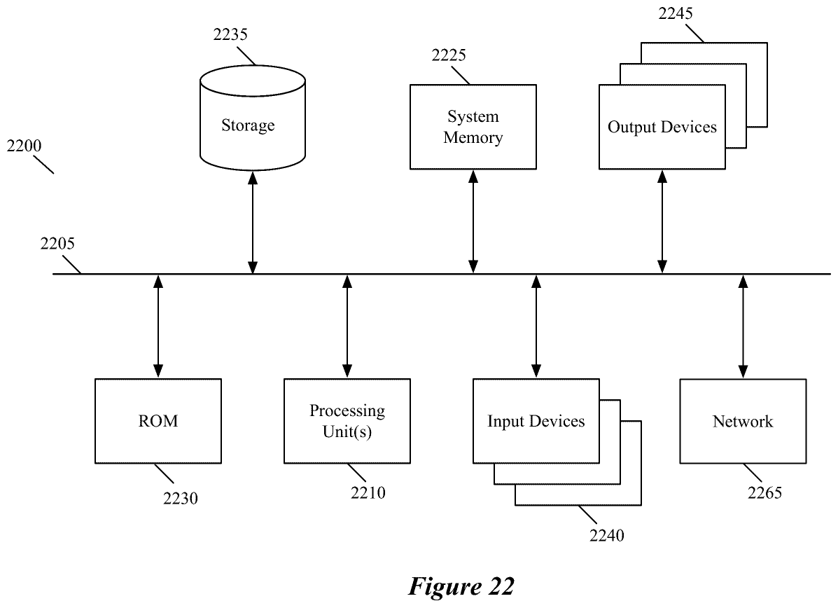

FIG. 22 conceptually illustrates an electronic system 2200 with which some embodiments of the invention are implemented. The electronic system 2200 may be a computer (e.g., a desktop computer, personal computer, tablet computer, server computer, mainframe, a blade computer etc.), phone, PDA, or any other sort of electronic device. As shown, the electronic system includes various types of computer readable media and interfaces for various other types of computer readable media. Specifically, the electronic system 2200 includes a bus 2205, processing unit(s) 2210, a system memory 2225, a read-only memory 2230, a permanent storage device 2235, input devices 2240, and output devices 2245.

The bus 2205 collectively represents all system, peripheral, and chipset buses that communicatively connect the numerous internal devices of the electronic system 2200. For instance, the bus 2205 communicatively connects the processing unit(s) 2210 with the read-only memory (ROM) 2230, the system memory 2225, and the permanent storage device 2235. From these various memory units, the processing unit(s) 2210 retrieve instructions to execute and data to process in order to execute the processes of the invention. The processing unit(s) may be a single processor or a multi-core processor in different embodiments.

The ROM 2230 stores static data and instructions that are needed by the processing unit(s) 2210 and other modules of the electronic system. The permanent storage device 2235, on the other hand, is a read-and-write memory device. This device is a non-volatile memory unit that stores instructions and data even when the electronic system 2200 is off. Some embodiments of the invention use a mass-storage device (such as a magnetic or optical disk and its corresponding disk drive) as the permanent storage device 2235.

Other embodiments use a removable storage device (such as a floppy disk, flash drive, etc.) as the permanent storage device. Like the permanent storage device 2235, the system memory 2225 is a read-and-write memory device. However, unlike storage device 2235, the system memory is a volatile read-and-write memory, such a random access memory. The system memory stores some of the instructions and data that the processor needs at runtime. In some embodiments, the invention's processes are stored in the system memory 2225, the permanent storage device 2235, and/or the read-only memory 2230. From these various memory units, the processing unit(s) 2210 retrieve instructions to execute and data to process in order to execute the processes of some embodiments.

The bus 2205 also connects to the input and output devices 2240 and 2245. The input devices enable the user to communicate information and select commands to the electronic system. The input devices 2240 include alphanumeric keyboards and pointing devices (also called “cursor control devices”). The output devices 2245 display images generated by the electronic system. The output devices include printers and display devices, such as cathode ray tubes (CRT) or liquid crystal displays (LCD). Some embodiments include devices such as a touchscreen that function as both input and output devices.

Finally, as shown in FIG. 22, bus 2205 also couples electronic system 2200 to a network 2265 through a network adapter (not shown). In this manner, the computer can be a part of a network of computers (such as a local area network (“LAN”), a wide area network (“WAN”), or an Intranet, or a network of networks, such as the Internet. Any or all components of electronic system 2200 may be used in conjunction with the invention.

Some embodiments include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, read-only and recordable Blu-Ray® discs, ultra density optical discs, any other optical or magnetic media, and floppy disks. The computer-readable media may store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some embodiments are performed by one or more integrated circuits, such as application specific integrated circuits (ASICs) or field programmable gate arrays (FPGAs). In some embodiments, such integrated circuits execute instructions that are stored on the circuit itself.

As used in this specification, the terms “computer”, “server”, “processor”, and “memory” all refer to electronic or other technological devices. These terms exclude people or groups of people. For the purposes of the specification, the terms display or displaying means displaying on an electronic device. As used in this specification, the terms “computer readable medium,” “computer readable media,” and “machine readable medium” are entirely restricted to tangible, physical objects that store information in a form that is readable by a computer. These terms exclude any wireless signals, wired download signals, and any other ephemeral or transitory signals.

While the invention has been described with reference to numerous specific details, one of ordinary skill in the art will recognize that the invention can be embodied in other specific forms without departing from the spirit of the invention. For instance, a number of the figures conceptually illustrate processes. The specific operations of these processes may not be performed in the exact order shown and described. The specific operations may not be performed in one continuous series of operations, and different specific operations may be performed in different embodiments. Furthermore, the process could be implemented using several sub-processes, or as part of a larger macro process. Therefore, one of ordinary skill in the art would understand that the invention is not to be limited by the foregoing illustrative details, but rather is to be defined by the appended claims.

1. A method for performing rule checks on a set of shapes in a layout that is used in a process for designing or manufacturing components on a substrate, the method comprising:
for each particular pixel in a plurality of pixels that lie along a boundary of a particular shape, dynamically generating an edge that traverses through the particular pixel to specify a portion of the boundary that lies along the particular pixel; and
using each generated edge to perform a rule check operation to determine whether any shape violates a rule that is enforced on the layout.

2. The method of claim 1, wherein using each generated edge comprises using a spacing rule check with respect to pairs of edges that are dynamically generated for pairs of shapes to determine whether the pair of edges are closer than a desired minimum spacing.

3. The method of claim 1, wherein using each generated edge comprises using a width check with respect to pairs of edges that are dynamically generated for opposing sides of one shape to determine whether the opposing edges are closer than a desired minimum width to indicate that the shape has too small a width at one region in the shape.

4. The method of claim 1, wherein each pixel has one of three types of pixel values, which are a first type of pixel values indicative of a pixel being completely within a shape, a second type of pixel value indicative of a pixel being completely outside of any shape, and a third type of pixel value for a pixel that is along an edge of a shape.

5. The method of claim 4, wherein the third type of pixel values are fractional values, while the first and second types of pixel values are 1 and 0 values.

6. The method of claim 4, wherein dynamically generating the edge comprises dynamically generating the edge for each pixel that has a third type of pixel value.

7. The method of claim 1, wherein dynamically generating the edge comprises using a marching-square process to draw the edge.

8. The method of claim 7, wherein
the marching-square process produces piecewise linear (PWL) edges to represent the boundaries of shapes in the layout, and
dynamically generating the edge further comprises converting at least one PWL edge defined by the marching square process to a curvilinear edge to represent a curvilinear boundary along at least one shape in the layout.

9. The method of claim 8, wherein dynamically generating the edge further comprises adjusting at least one PWL or curvilinear edge to cover an area that more closely matches a pixel value that is assigned to a region traversed by the generated edge.

10. The method of claim 1, wherein the layout is a mask layout and the rule check comprises a mask rule spacing check that ensures that no two edges of two nearby shapes are closer than a threshold distance.

11. The method of claim 1, wherein the layout is a mask layout, and the rule check comprises a mask rule width check that ensures that no two edges of one shape are closer than a threshold distance.

12. The method of claim 1, wherein the layout is a design layout, and the rule check comprises a design rule spacing check that ensures that no two edges of two nearby shapes are closer than a threshold distance.

13. The method of claim 1, wherein the layout is a design layout, and the rule check comprises a design rule width check that ensures that no two edges of one shape are closer than a threshold distance.

14. The method of claim 1 further comprising performing a rasterization operation to generate a pixel-based definition of each shape from a contour-based definition that is used to define each shape in the layout.

15. The method of claim 1, wherein using each generated edge to perform the rule check operation comprises
for each pixel of the plurality of pixels in the layout:
defining a search window that identifies a search area about the pixel;
identifying within the search window one or more pairs of pixels that lie along one or more boundaries of one or more shapes in the layout; and
determining whether any identified pair of pixels violate the rule check.

16. The method of claim 15, wherein determining whether any identified pair of pixels violate the rule check comprises determining whether two edges dynamically generated for the pair of pixels violate the rule check.

17. A non-transitory machine readable medium storing a program for execution by at least one processing unit and for performing rule checks on a set of shapes in a layout that is used in a process for designing or manufacturing components on a substrate, the program comprising sets of instructions for:
for each particular pixel in a plurality of pixels that lie along a boundary of a particular shape, dynamically generating an edge that traverses through the particular pixel to specify a portion of the boundary that lies along the particular pixel; and
using each generated edge to perform a rule check operation to determine whether any shape violates a rule that is enforced on the layout.

18. The non-transitory machine readable medium of claim 17, wherein the set of instructions for using each generated edge comprises a set of instructions for using a spacing rule check with respect to pairs of edges that are dynamically generated for pairs of shapes to determine whether the pair of edges are closer than a desired minimum spacing.

19. The non-transitory machine readable medium of claim 17, wherein the set of instructions for using each generated edge comprises a set of instructions for using a width check with respect to pairs of edges that are dynamically generated for opposing sides of one shape to determine whether the opposing edges are closer than a desired minimum width to indicate that the shape has too small a width at one region in the shape.

20. The non-transitory machine readable medium of claim 17, wherein each pixel has one of three types of pixel values, which are a first type of pixel values indicative of a pixel being completely within a shape, a second type of pixel value indicative of a pixel being completely outside of any shape, and a third type of pixel value for a pixel that is along an edge of a shape.
